(19) United States
(12) Patent Application Publication
(10) Pub. No.: US 2009/0232362 A1
(43) Pub. Date: Sep. 17, 2009

(54) BIOMETRIC INFORMATION ACQUISITION APPARATUS AND BIOMETRIC AUTHENTICATION APPARATUS

(75) Inventors: Hiroyasu Otsubo, Osaka (JP); Akito Sakemoto, Osaka (JP)

Correspondence Address: BIRCH STEWART KOLASCH & BIRCH, PO BOX 747, FALLS CHURCH, VA, 22040-0747, US

(73) Assignee: HITACHI MAXELL, LTD., Ibaraki-shi (JP)

(21) Appl. No.: 12/402,292

(22) Filed: Mar. 11, 2009

(30) Foreign Application Priority Data
Mar. 12, 2008 (JP) 2008-061998
May 20, 2008 (JP) 2008-131750
May 30, 2008 (JP) 2008-143487
Dec. 8, 2008 (JP) 2008-312174

(51) Int. Cl. G06K 9/00; H01L 27/00

(52) U.S. Cl. 382/115; 250/208.1

(57) ABSTRACT

A biometric information acquisition apparatus includes a light illuminator to illuminate a subject with light at least over a range corresponding to a pixel arrangement region where a plurality of pixels to receive light from the subject are arranged, and an imager placed on the same plane as the light illuminator and including the pixel arrangement region where the plurality of pixels are arranged.

### BACKGROUND OF THE INVENTION

1. Field of the Invention

The present invention relates to a biometric information acquisition apparatus and a biometric authentication apparatus.

2. Description of Related Art

Fingerprint authentication, vein authentication and iris authentication are known among biometric authentication technologies. Particularly, vein authentication attracts attention as promising technology because forgery of authentication information is more difficult compared to fingerprint authentication and authentication can be executed relatively easily.

Techniques related to vein authentication are disclosed in Japanese Unexamined Patent Application Publication No. 2001-119008 (hereinafter referred to as the patent document 1) and Japanese Unexamined Patent Application Publication No. 2006-218019 (hereinafter referred to as the patent document 2) The patent document 1 discloses the imaging apparatus that is used for biometric authentication. In this imaging apparatus, the light source (100), the support (300) and the image authentication portion (200) are stacked on top of each other, thereby reducing the size of the imaging apparatus. The patent document 2 discloses the apparatus that acquires a blood vessel image using the line sensor.

Further, Japanese Unexamined Patent Application Publication No. 2001-344213 (hereinafter referred to as the patent document 3) discloses the biometric authentication apparatus that includes the imager, the host device, the authentication portion and the memory portion. The imager, the host device, the authentication portion and the memory portion are connected through the external bus. Image data captured by the imager is output to the external bus. At the time of performing authentication, biometric information prestored in the memory portion is output to the external bus.

Furthermore, the biometric information acquisition apparatus disclosed in Japanese Unexamined Patent Application Publication No. 2007-257307 (hereinafter referred to as the patent document 4) moves the sliding member including the line sensor by the driver to sequentially capture images of a part of a subject.

In vein authentication, it is necessary to apply near-infrared light over a given range of a subject for the purpose of acquiring high-quality vein images. In order to apply near-infrared light all over a given range of a subject, it is necessary to keep a light source away from the subject or prepare a large number of light sources. This causes enlargement of a biometric information acquisition apparatus that acquires vein images, which increases a proportion to a main equipment body.

### SUMMARY OF THE INVENTION

The present invention has been accomplished to address the above concern, and an object of the present invention is thus to further reduce the size of a biometric information acquisition apparatus while ensuring application of light over a given range of a subject.

According to an embodiment of the present invention, there is provided a biometric information acquisition apparatus that includes a light illuminator that illuminates a subject with light at least over a range corresponding to a pixel arrangement region where a plurality of pixels to receive light from the subject are arranged, and an imager placed on the same plane as the light illuminator and including the pixel arrangement region.

In this biometric information acquisition apparatus, one or more pixel arrays each including the plurality of pixels may be formed in the pixel arrangement region.

Further, the light illuminator may include a light guide extending along a pixel arrangement direction in the pixel array.

The light illuminator may include an organic light emitting layer extending along a pixel arrangement direction in the pixel array.

The light illuminator may include a plurality of light emitting devices arranged at substantially regular intervals.

The light illuminator may uniformize light within a range corresponding to the pixel array and output uniform light.

The light guide described above may have a light output surface extending along a pixel arrangement direction in the pixel array.

Further, the light guide and the imager may be sequentially arranged in a direction intersecting with the pixel arrangement direction in the pixel array.

The above biometric information acquisition apparatus may further include a substrate where at least the light guide and the imager are mounted.

The above biometric information acquisition apparatus may further include a capacitance sensor including one or more electrode arrays each having a plurality of electrodes arranged along the pixel arrangement direction in the pixel array, and the capacitance sensor and the imager may be sequentially arranged in a direction intersecting with the pixel arrangement direction in the pixel array.

Alternatively, in the biometric information acquisition apparatus described above, the light illuminator may include a first light source and a second light source to emit light with different wavelengths, a first light guide to guide light emitted from the first light source and output the light to the subject, and a second light guide to guide light emitted from the second light source and output the light to the subject, and the first light guide, the second light guide and the imager may be arranged in a direction intersecting with a pixel arrangement direction in the pixel array.

In the above biometric information acquisition apparatus, the first light source may emit near-infrared light, and the second light source may emit visible light.

The biometric information acquisition apparatus described above may further include a plurality of lenses arranged corresponding to the plurality of pixels.

Further, the biometric information acquisition apparatus described above may further include a light shielding layer placed between the plurality of lenses and the imager, and the light shielding layer may have a plurality of optical openings corresponding to optical axes of the lenses.

According to another embodiment of the present invention, there is provided a biometric authentication apparatus that includes a light illuminator to illuminate a subject with light at least over a range corresponding to a pixel arrangement region where a plurality of pixels to receive light from the subject are arranged, and a semiconductor device placed on the same plane as the light illuminator and including the pixel arrangement region where the plurality of pixels are arranged, the semiconductor device including an imaging region to capture an image of the subject at least in the range corresponding to the pixel arrangement region, an authentication region to perform authentication by comparing biometric information acquired by imaging in the imaging region with prestored biometric information, and a first transfer region to transfer the biometric information acquired by imaging in the imaging region from the imaging region to the authentication region.

In this biometric authentication apparatus, the semiconductor device may further include an interface region to supply an authentication result in the authentication region to an external host device, and a second transfer region to transfer a signal indicating an authentication result in the authentication region to the interface region.

In the above biometric authentication apparatus, the semiconductor device may further include an encryption region to encrypt an authentication result in the authentication region.

In the above biometric authentication apparatus, the semiconductor device may further include a control region to control luminance of light illuminated on the subject.

According to the embodiments of the present invention described above, it is possible to further reduce the size of a biometric information acquisition apparatus while ensuring application of light over a given range of a subject.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a schematic perspective view showing a biometric information acquisition apparatus according to a first embodiment of the present invention;

FIG. 2A is a schematic diagram showing the cross-sectional structure of the biometric information acquisition apparatus according to the first embodiment of the present invention;

FIG. 2B is a schematic diagram showing the cross-sectional structure of the biometric information acquisition apparatus according to the first embodiment of the present invention;

FIG. 2C is a schematic diagram showing the cross-sectional structure of the biometric information acquisition apparatus according to the first embodiment of the present invention;

FIG. 3A is an explanatory view to describe the function of a light guide according to the first embodiment of the present invention;

FIG. 3B is an explanatory view to describe the function of the light guide according to the first embodiment of the present invention;

FIG. 4 is an explanatory view showing the topside structure of the biometric information acquisition apparatus according to the first embodiment of the present invention;

FIG. 5 is an explanatory view to describe the function of the biometric information acquisition apparatus according to the first embodiment of the present invention;

FIG. 6 is a block diagram showing the schematic configuration of a biometric authentication apparatus according to the first embodiment of the present invention;

FIG. 7 is a flowchart to describe the operation of the biometric authentication apparatus according to the first embodiment of the present invention;

FIG. 8A is an explanatory view to describe the movement of a finger;

FIG. 8B is an explanatory view to describe the movement of a finger;

FIG. 9A is an explanatory view to describe the positional relationship of acquired vein images;

FIG. 9B is an explanatory view to describe the positional relationship of acquired vein images;

FIG. 10 is a schematic perspective view showing a biometric information acquisition apparatus according to a second embodiment of the present invention;

FIG. 11 is a timing chart to describe the operation of the biometric information acquisition apparatus according to the second embodiment of the present invention;

FIG. 12 is a schematic perspective view showing a biometric information acquisition apparatus according to a third embodiment of the present invention;

FIG. 13 is a schematic perspective view showing a biometric information acquisition apparatus according to a fourth embodiment of the present invention;

FIG. 14 is a schematic perspective view showing a biometric information acquisition apparatus according to a fifth embodiment of the present invention;

FIG. 15 is a schematic diagram showing the cross-sectional structure of an area light source according to the fifth embodiment of the present invention;

FIG. 16 is a block diagram showing the configuration of a biometric authentication system according to a sixth embodiment of the present invention;

FIG. 17 is a schematic diagram showing a biometrics IC according to the sixth embodiment of the present invention;

FIG. 18 is a schematic diagram showing another biometrics IC according to the sixth embodiment of the present invention;

FIG. 19 is a schematic diagram showing a connection between the biometrics IC and a host device;

FIG. 20 is a schematic diagram showing a biometric authentication apparatus according to a seventh embodiment of the present invention;

FIG. 21 is a block diagram showing the configuration of a biometric authentication system according to an eighth embodiment of the present invention;

FIG. 22 is a block diagram showing the configuration of a biometric authentication apparatus according to a ninth embodiment of the present invention;

FIG. 23 is a front view schematically showing a biometric information acquisition portion according to the ninth embodiment of the present invention;

FIG. 24 is a front view schematically showing a placing table;

FIG. 25 is a rear view schematically showing the placing table;

FIG. 26 is a bottom view schematically showing the placing table;

FIG. 27A is a front view schematically showing a casing member that contains a light source, an imager and so on;

FIG. 27B is a partially enlarged view schematically showing a line sensor;

FIG. 28 is a front view schematically showing another placing table;

FIG. 29 is a front view schematically showing a biometric information acquisition portion according to a tenth embodiment of the present invention;

FIG. 30 is a rear view schematically showing another placing table;

FIG. 31A is a front view schematically showing a pattern;

FIG. 31B is a front view schematically showing a pattern;

FIG. 31C is a front view schematically showing a pattern;

FIG. 31D is a front view schematically showing a pattern;

FIG. 32 is a view showing a signal indicating read positional information and a line signal obtained by capturing an image of a finger;

FIG. 33 is a bock diagram schematically showing the configuration of a biometric authentication apparatus according to the tenth embodiment of the present invention;

FIG. 34 is a bock diagram schematically showing the configuration of a biometric authentication apparatus according to an eleventh embodiment of the present invention;

FIG. 35 is a front view schematically showing a pattern having a light amount adjusting pattern; and

FIG. 36 is a view showing a signal obtained by performing imaging while controlling the light amount of a light source.

### DESCRIPTION OF THE PREFERRED EMBODIMENTS

Exemplary embodiments of the present invention are described hereinafter with reference to the drawings. Each embodiment is simplified for convenience of description. The drawings are given in simplified form by way of illustration only, and thus are not to be considered as limiting the present invention. The drawings are given merely for the purpose of explanation of technological matters, and they do not show the accurate scale or the like of each element shown therein. The same elements are denoted by the same reference symbols, and the redundant explanation is omitted. The terms indicating the directions, such as up, down, left and right, are used on condition that each drawing is viewed from the front.

### First Embodiment

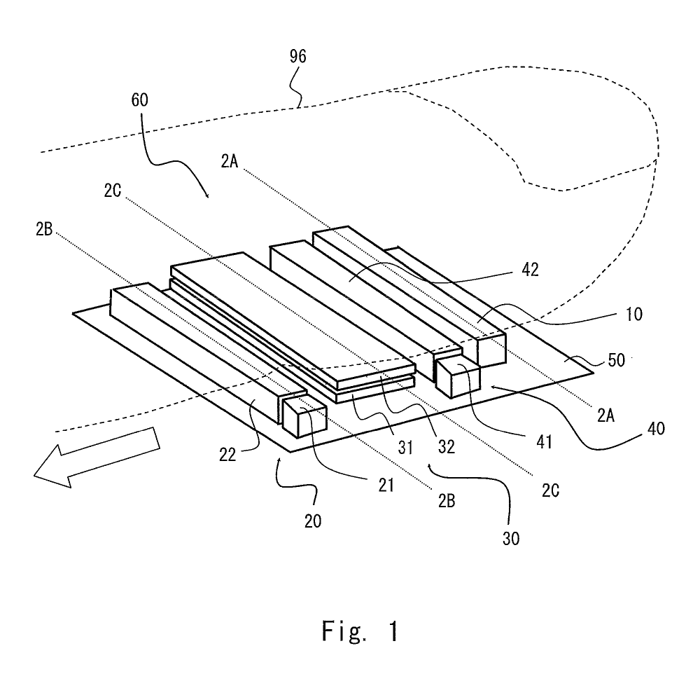

The configuration and the functions of a biometric information acquisition apparatus are described hereinafter with reference to FIGS. 1 to 5.

FIG. 1 is a schematic perspective view of a biometric information acquisition apparatus 60. As shown in FIG. 1, the biometric information acquisition apparatus 60 includes a light source 21, a light guide 22, an image pickup device (imager) 31, an optical functional layer 32, a light source 41, a light guide 42, a capacitance sensor 10, and a wiring board (packaging substrate) 50. The light source 21, the light guide 22, the image pickup device 31, the light source 41, the light guide 42 and the capacitance sensor 10 which are supported by the wiring board 50 and placed on the same plane. The light guide 22, the image pickup device 31, the light guide 42 and the capacitance sensor 10 are arranged in this order from left to right. The biometric information acquisition apparatus 60 is used for vein authentication.

The light source 21 and the light guide 22 are referred to collectively as a light illumination unit 20. Likewise, the light source 41 and the light guide 42 are referred to collectively as a light illumination unit 40. Further, the image pickup device 31 and the optical functional layer 32 are referred to collectively as an image acquisition unit 30. The light illumination unit is equivalent to a light illuminator.

The biometric information acquisition apparatus 60 acquires a plurality of vein images of a finger (subject) 96 placed above at different timings. Based on the vein images acquired by the biometric information acquisition apparatus 60, an image for biometric authentication is created.

The biometric information acquisition apparatus 60 acquires a plurality of fingerprint images of the finger 96 placed above. Based on the fingerprint images acquired by the biometric information acquisition apparatus 60, the moving direction of the finger 96 and the moving amount per unit time of the finger 96 are obtained.

A biometric authentication apparatus that incorporates the biometric information acquisition apparatus 60 combines the vein images to create an image for biometric authentication based on the moving direction of the finger 96 and the moving amount per unit time of the finger 96. The relative positions of the acquired vein images are obtained from the moving direction of the finger 96 and the moving amount per unit time of the finger 96. The acquisition of vein images and the acquisition of fingerprint images are performed at the same timing in the biometric information acquisition apparatus 60.

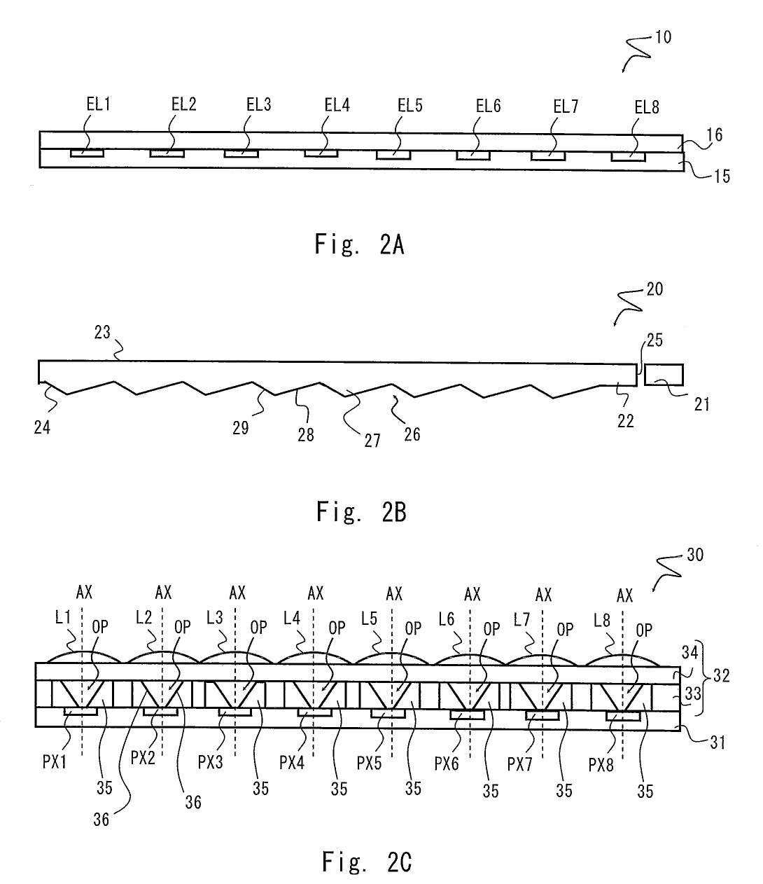

FIGS. 2A to 2C are schematic diagrams showing the partial cross-sectional structures of the biometric information acquisition apparatus 60. FIG. 2A shows the schematic cross section along line 2A-2A in FIG. 1. FIG. 2B shows the schematic cross section along line 2B-2B in FIG. 1. FIG. 2C shows the schematic cross section along line 2C-2C in FIG. 1.

As shown in FIG. 2A, the capacitance sensor 10 includes a sensor substrate 15 and a protective film 16. On the top face of the sensor substrate 15, an electrode array composed of a plurality of electrodes EL1 to EL8 arranged in a row. The capacitance sensor 10 serves as a fingerprint detection unit that detects the movement of the fingerprint pattern of the finger 96 (a means of detecting the movement of the fingerprint pattern of the finger 96).

The capacitance sensor 10 detects the values of capacitances formed between the finger 96 placed above and the respective electrodes EL1 to EL8 using capacitance detectors connected between the respective electrodes EL1 to EL8. A capacitance value detected by each capacitance detector corresponds to the distance between each electrode EL1 to EL8 and the skin of the finger 96. A fingerprint is formed in the surface of the finger 96. When the finger 96 is placed on the capacitance sensor 10, the capacitance distribution, which is output from the capacitance detectors connected to the respective electrodes EL1 to EL8, corresponds to the fingerprint pattern on the electrodes EL1 to EL8. In this way, the capacitance sensor 10 acquires the fingerprint images of the finger 96 placed above. The arrangement of the electrodes is arbitrary. For example, the electrodes may be arranged in matrix. The fingerprint images (information) detected by the capacitance sensor 10 are used for obtaining the moving direction of the finger 96 and the moving amount per unit time of the finger 96.

The protective film 16 shown in FIG. 2A is a thin film that protects the electrodes ELI to EL8 from the outside world. The protective film 16 is deposited on the sensor substrate 15. The material of the protective film 16 may be transparent resin, glass or the like, for example.

As shown in FIG. 2B, the light illumination unit 20 includes the light source 21 and the light guide 22. The structure of the above-described light illumination unit 40 is the same as the structure of the light illumination unit 20. Thus, repeated description is omitted.

The light source 21 is a semiconductor optical element with a mold-packaged semiconductor chip such as a semiconductor light emitting diode (LED) or a semiconductor laser diode (LD). By applying a current between the electrodes, the light source 21 outputs light with a wavelength in the near-infrared region (which is a wavelength of 600 nm to 1000 nm, and it is 760 nm or 870 nm in this example).

The light guide 22 is substantially transparent to the output light from the light source 21. The light guide 22 is a planar member having a top surface 23, a bottom surface 24 and a side surface 25. The light source 21 is placed opposite to the side surface 25 of the light guide 22. The material of the light guide 22 is arbitrary. For example, the light guide 22 may be made of quartz, resin, glass or the like.

The bottom surface 24 of the light guide 22 has a plurality of grooves 26 extending in the direction perpendicular to the sheet. Because of the grooves 26, a plurality of projections 27 and a plurality of reflective surfaces 28 and 29 are formed on the bottom surface 24 of the light guide 22.

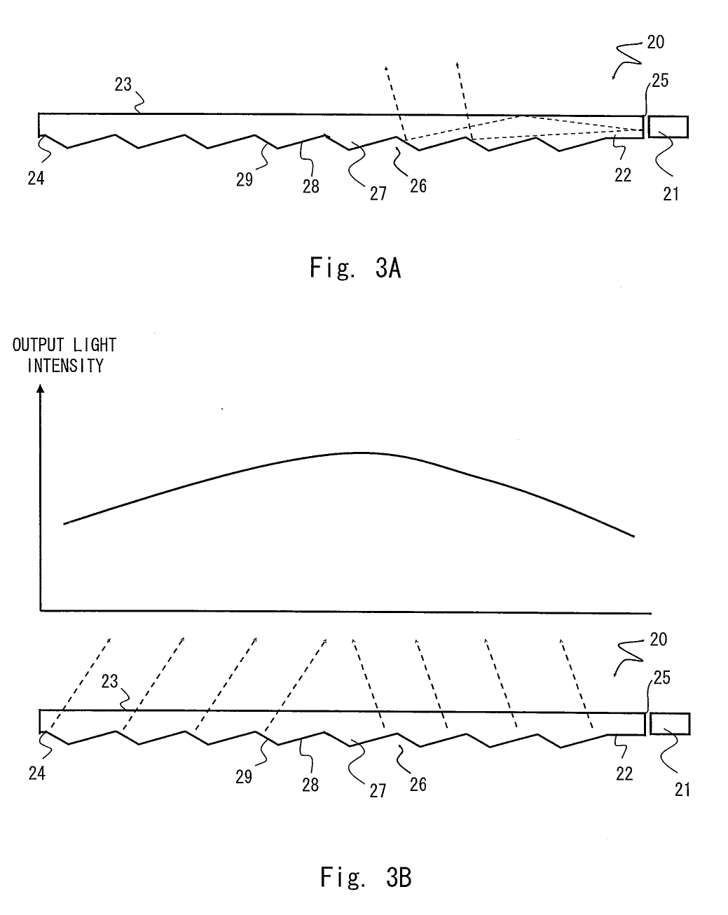

Referring to FIGS. 3A and 3B, the functions of the light guide 22 are described hereinafter. As shown in FIG. 3A, the output light from the light source 21 which has entered the light guide 22 through the side surface (light incident surface) 25 of the light guide 22 propagates to the left of the sheet within the light guide 22 and is then reflected by the reflective surface 29 and output through the top surface (light output surface) 23. By arranging the reflective surfaces 29 appropriately, it is possible to obtain the output light intensity distribution as shown in FIG. 3B, for example. Specifically, the distribution can be obtained in which the output light intensity at the center of the light guide 22 is higher than the output light intensity at the ends of the light guide 22.

Referring back to FIG. 2C, the image acquisition unit 30 includes the image pickup device 31 and the optical functional layer 32.

The image pickup device 31 is a semiconductor imager (which is a so-called line sensor) that includes a pixel array composed of a plurality of pixels PX1 to PX8 arranged in a row. The pixels PX1 to PX8 may be photodiodes, for example. Each pixel PX1 to PX8 outputs a current having a value corresponding to the incident light intensity. An output current from each pixel PX1 to PX8 is converted into a voltage by an I/V converter and finally converted into a digital signal by an A/D converter.

The optical functional layer 32 includes a light shielding layer 33 and a lens substrate 34. The light shielding layer 33 is placed on the image pickup device 31. The lens substrate 34 is placed on the light shielding layer 33.

The light shielding layer 33 has a plurality of light shielding portions 35 respectively corresponding to the pixels PX1 to PX8. The lens substrate 34 has a plurality of lenses L1 to L8 respectively corresponding to the pixels PX1 to PX8. The lenses L1 to L8 are convex microlenses with a lens diameter of about several to several hundreds of micrometers. The light shielding portions 35 absorb incident light. The light shielding portions 35 are made of black resin, for example. Each light shielding mechanism 35 has an opening OP corresponding to the optical axis AX of each lens L1 to L8.

The light that is incident on the image acquisition unit 30 propagates as follows. The light input to the respective lenses L1 to L8 is converged by the lens action at each lens, passes through the substrate part of the lens substrate 34, then passes through the opening OP of the light shielding mechanism 35 of the light shielding layer 33 and is finally input to each pixel PX1 to PX8 of the image pickup device 31.

By setting the lens diameter of the respective lenses L1 to L8 appropriately, it is possible to suitably acquire the vein images of the finger 96.

Further, the light shielding portions 35 of the light shielding layer 33 effectively separates optical channels between the lenses and the pixels, thereby effectively avoiding crosstalk between the optical channels. It is thereby possible to improve the quality of images finally obtained by the image pickup device 31.

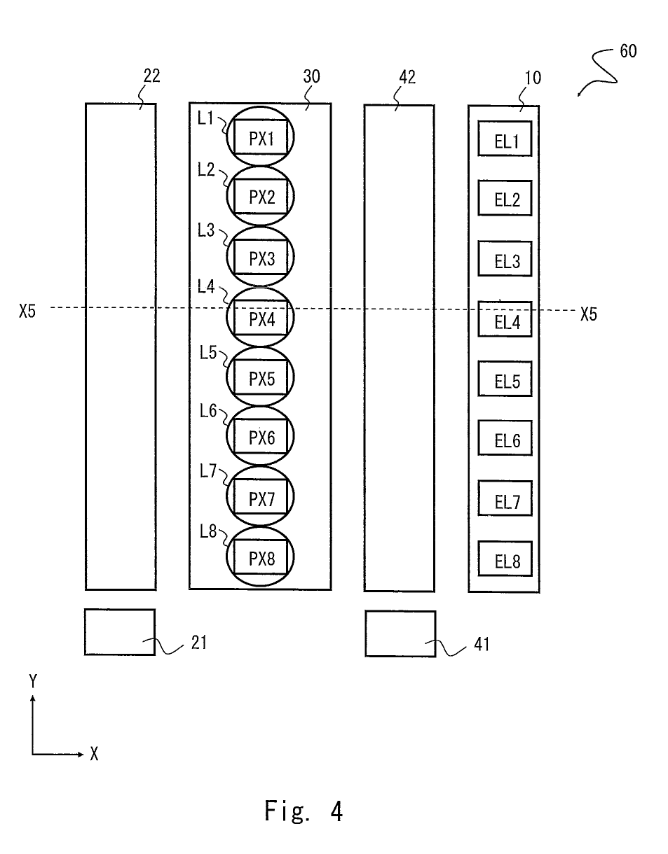

FIG. 4 is an explanatory view showing the topside structure of the biometric information acquisition apparatus 60. In FIG. 4, an x-axis and a y-axis orthogonal to each other are set.

As shown in FIG. 4, the light guide 22 is a longitudinal member along the y-axis. The light guide 42 is the same as the light guide 22.

The plurality of pixels PX1 to PX8 are arranged along the y-axis. Likewise, the plurality of lenses L1 to L8 are arranged along the y-axis. Likewise, the plurality of electrodes EL1 to EL8 are arranged along the y-axis. Thus, the arrangement direction of the pixels, the arrangement direction of the lenses and the arrangement direction of the electrodes are substantially parallel to one another. Further, the longitudinal direction of each light guide is substantially parallel to the arrangement direction of the pixels, the arrangement direction of the lenses and the arrangement direction of the electrodes. The light guide 22, the image acquisition unit 30 (image pickup device 31), the light guide 42 and the capacitance sensor 10 are arranged in this order along the x-axis.

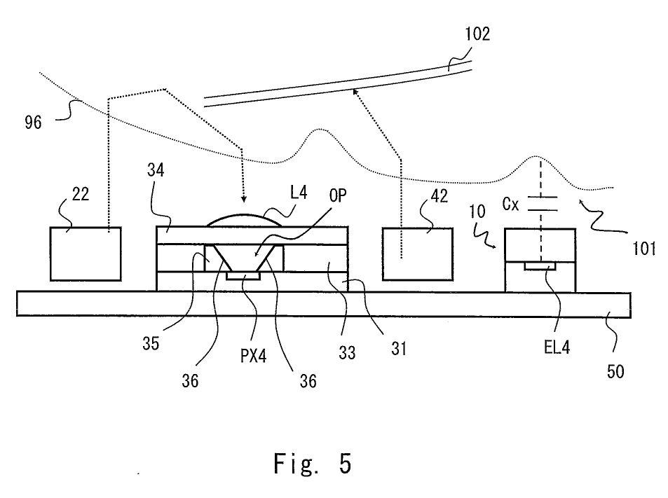

Referring then to FIG. 5, the functions of the biometric information acquisition apparatus 60 are additionally described below. FIG. 5 is a schematic diagram showing the cross-sectional structure along line x5-x5 in FIG. 4.

As shown in FIG. 5, the output light from the light source 21 is applied to the finger 96 through the light guide 22. The light having passed through the finger 96 is input to the image acquisition unit 30. On the other hand, the output light from the light source 41 is applied to the finger 96 through the light guide 42. The output light from the light source 41 is partially absorbed by a vein 102 of the finger 96. The output light from the light source 21 is absorbed by the vein 102 of the finger 96. The image pickup device 31 acquires vein images by the plurality of pixels PX1 to PX8.

As schematically shown in FIG. 5, the capacitance sensor 10 detects the value of a parasitic capacitance Cx formed between the electrode EL4 of the sensor substrate 15 and the skin of the finger 96. The skin of the finger 96 has a plurality of grooves 101 that form a fingerprint pattern. The value of the parasitic capacitance Cx corresponds to the distance between the top surface of the electrode and the skin of the finger 96. The capacitance sensor 10 acquires fingerprint images of the finger 96 in the range corresponding to the placement range of the electrodes EL1 to EL8.

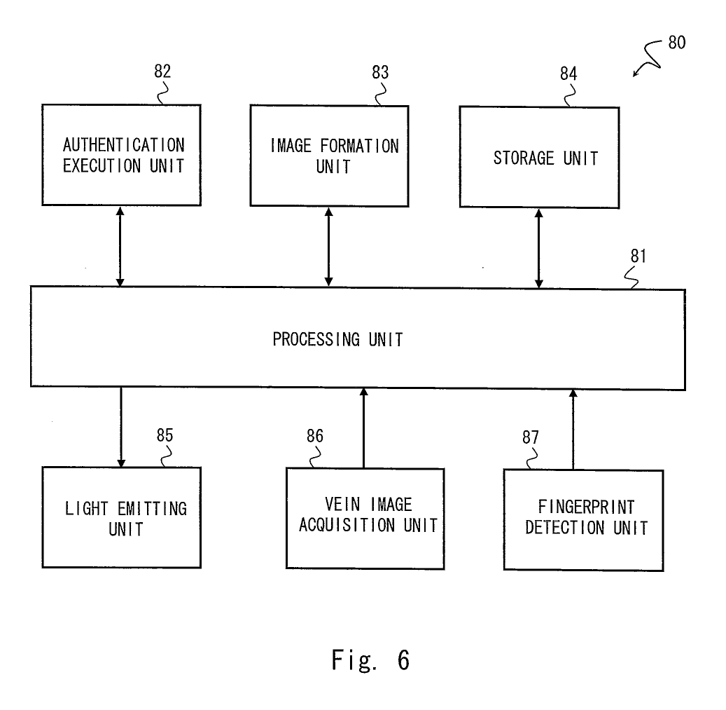

The structure and the operation of a biometric authentication apparatus that incorporates the biometric information acquisition apparatus 60 are described hereinafter with reference to FIGS. 6 to 9B.

As shown in FIG. 6, a biometric authentication apparatus 80 includes a processing unit 81, an authentication execution unit 82, an image formation unit 83, a storage unit 84, a light emitting unit 85, a vein image acquisition unit 86 and a fingerprint detection unit 87. The light emitting unit 85 is equivalent to the light illumination units 20 and 40. The vein image acquisition unit 86 is equivalent to the image acquisition unit 30. The fingerprint detection unit 87 is equivalent to the capacitance sensor 10. The biometric authentication apparatus 80 is configured by a general computer having the biometric information acquisition apparatus as an interface. The configuration of the biometric authentication apparatus 80 is not limited to the one shown in FIG. 6.

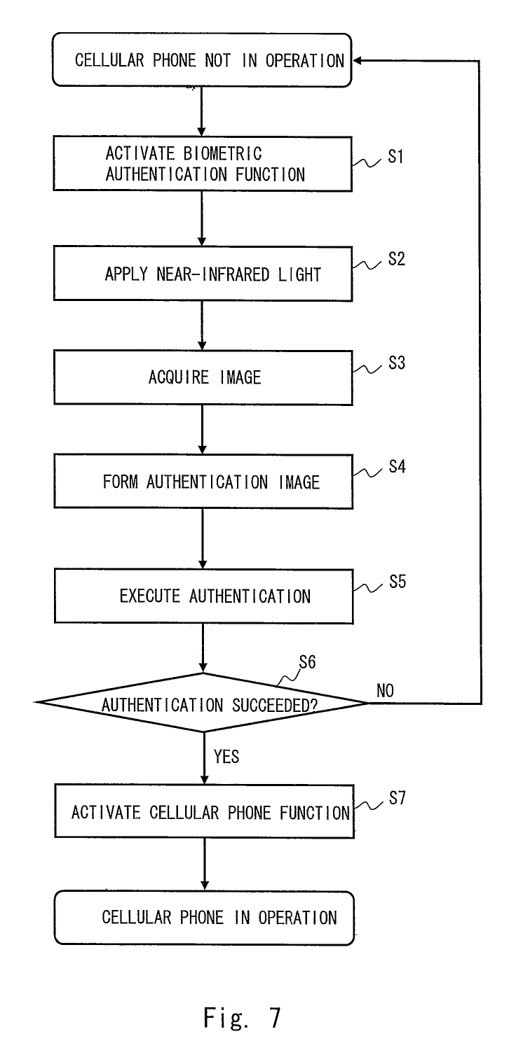

The biometric authentication apparatus 80 operates as shown in FIG. 7. It is assumed that the biometric authentication apparatus 80 is incorporated into a cellular phone.

First, the cellular phone that incorporates the biometric authentication apparatus 80 is in a non-operating state.

Next, the biometric authentication function of the cellular phone is activated (S1). A specific method of activating the biometric authentication function is arbitrary. For example, the biometric authentication function may be activated when a user presses a certain button of the cellular phone.

Following the activation of the biometric authentication function, light is applied to the finger 96 from the light emitting unit 85 (S2). Specifically, the light illumination units 20 and 40 of the biometric information acquisition apparatus 60 illuminate the finger 96 with light. In the step S2, the finger 96 moves toward the front along the arrow of FIG. 1.

Then, the vein image acquisition unit 86 acquires a plurality of vein images at very short time intervals, and the fingerprint detection unit 87 acquires a plurality of fingerprint images at very short time intervals as well (S3). Specifically, the biometric information acquisition apparatus 60 acquires a plurality of vein images of the finger 96 placed on the image acquisition unit 30 at very short time intervals. Likewise, the biometric information acquisition apparatus 60 acquires a plurality of fingerprint images of the finger 96 placed on the capacitance sensor 10 at very short time intervals. In this example, the biometric information acquisition apparatus 60 acquires the vein images and the fingerprint images at the same timing.

After that, the image formation unit 83 forms a vein image for authentication (S4). Because a line sensor is used in this embodiment, only the vein image in the range corresponding to one pixel array is obtained. Thus, in order to achieve highly accurate vein authentication, the image pickup device 31 acquires a plurality of vein images during the movement of the finger 96, and the image formation unit 83 forms one vein image from the plurality of vein images.

The image formation unit 83 obtains the moving direction of the finger 96 and the moving amount per unit time of the finger 96 from the plurality of fingerprint images acquired by the fingerprint detection unit 87 and forms a vein image for authentication from the plurality of vein images acquired by the vein image acquisition unit 86.

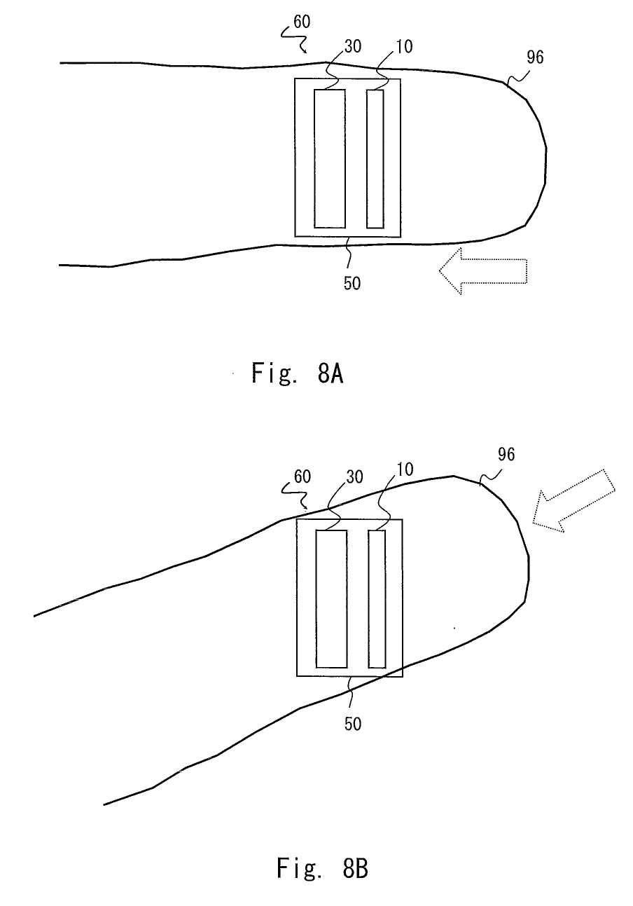

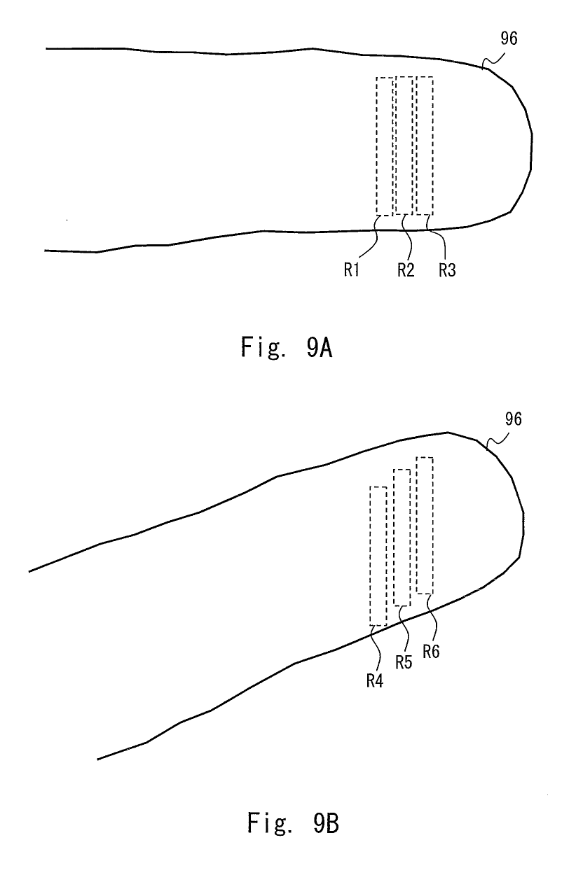

The operation of the image formation unit 83 is described hereinafter with reference to FIGS. 8A, 8B, 9A and 9B.

In some cases, the finger 96 moves horizontally across the biometric information acquisition apparatus 60 as schematically shown by the arrow in FIG. 8A. In other cases, the finger 96 moves diagonally across the biometric information acquisition apparatus 60 as schematically shown by the arrow in FIG. 8B.

In the case of FIG. 8A, the image pickup device 31 acquires vein images in the range of a region R1, a region R2 and a region R3 sequentially as schematically shown by the arrow in FIG. 9A. In the case of FIG. 8B, the image pickup device 31 acquires vein images in the range of a region R4, a region R5 and a region R6 sequentially as schematically shown by the arrow in FIG. 9B.

In the case of FIG. 8A, the image formation unit 83 horizontally combines the plurality of images acquired by the image pickup device 31 to form one vein authentication image. In the case of FIG. 8B, the image formation unit 83 diagonally combines the plurality of images acquired by the image pickup device 31 to form one vein authentication image.

When the image formation unit 83 forms a vein image for authentication from a plurality of vein images acquired by the vein image acquisition unit 86, the image formation unit 83 identifies the relative positions of the respective vein images acquired by the vein image acquisition unit 86 based on the plurality of fingerprint images acquired by the fingerprint detection unit 87.

A fingerprint pattern of the finger 96 has a certain regularity. Therefore, the image formation unit 83 can determine the moving direction of the finger 96 and determine the moving amount per unit time of the finger 96 by identifying the transition of the capacitance distributions sequentially output from the fingerprint detection unit 87.

Specifically, the image formation unit 83 compares the sequentially acquired capacitance distributions on the same principle as an optical mouse and identifies the same pattern of movement contained in the capacitance distributions. The moving amount per unit time and the moving direction of the finger 96 are thereby determined. The unit time corresponds to a frame interval (acquisition interval) of the capacitance distributions acquired by the fingerprint detection unit 87.

Alternatively, the image formation unit 83 may determine the moving direction of the finger 96 and determine the moving amount per unit time of the finger 96 by applying a given algorithm to the capacitance distributions sequentially output from the fingerprint detection unit 87.

Refer now back to FIG. 7.

The authentication execution unit 82 then executes authentication (S5). Specifically, the authentication execution unit 82 executes biometric authentication based on the authentication image output from the image formation unit 83 and the vein image prestored in the storage unit 84. For example, the authentication execution unit 82 determines that the authentication is succeeded if the number of parts where the way the veins are branched matches between the images is equal to or more than N (N is a natural number of 2 or above), and it determines that the authentication is failed if the number of parts where the way the veins are branched matches between the images is less than N (S6). Because a specific method of authentication depends on an image processing method, it is not limited to the above example.

If the authentication is succeeded, the function of the cellular phone that incorporates the biometric authentication apparatus 80 is activated (S7). Then, the cellular phone returns to a normal operating state. If, on the other hand, the authentication is failed, the cellular phone that incorporates the biometric authentication apparatus 80 remains in the non-operating state.

As described above, by incorporating the biometric authentication apparatus 80 into the cellular phone, the security of the cellular phone increases significantly.

In this embodiment, the biometric information acquisition apparatus 60 is miniaturized with use of the line sensor. Further, the image pickup device 31 and the light guide 22 are placed on the same plane. This sufficiently reduces the thickness of the biometric information acquisition apparatus 60. Because light from each light source is output through the top surface of each light guide (the surface facing the finger 96), the light is sufficiently applied over a desired range of the finger 96 without any inhibition. On the top surface of the image pickup device 31 (the surface facing the finger 96), a plurality of pixels are placed. Each light guide guides the input light to a desired light output surface through a plurality of reflective surfaces arranged appropriately.

Further, the components necessary for acquiring biometric information (the light source 21, the light guide 22, the image pickup device 31, the light source 41, the light guide 42 and the capacitance sensor 10) are mounted on the common wiring board 50, thereby implementing the modularity of the biometric information acquisition apparatus.

Furthermore, the optical functional layer 32 is placed on the image pickup device 31, thereby enabling the image pickup device 31 to acquire higher quality vein images. Adjustment of the focal length of the lens according to the depth of the vein from the skin of the finger 96 enables the image pickup device 31 to acquire clearer vein images. Placement of the light shielding layer having a plurality of openings corresponding to the optical axes of the lenses on the image pickup device 31 allows reduction of crosstalk between optical channels, thereby enabling the image pickup device 31 to acquire clearer vein images.

A procedure to manufacture the biometric information acquisition apparatus 60 is arbitrary, as long as the light source 21, the light guide 22, the image acquisition unit 30, the light source 41, the light guide 42 and the capacitance sensor 10, which are prepared beforehand, are mounted on the wiring board 50. A procedure to manufacture the image acquisition unit 30 is also arbitrary. The optical functional layer 32 is fabricated using normal semiconductor process technology (a thin film formation step, an etching step, a heating step etc.). The optical functional layer 32 fabricated in this manner is fixed on top of the image pickup device 31, thereby creating the image acquisition unit 30.

### Second Embodiment

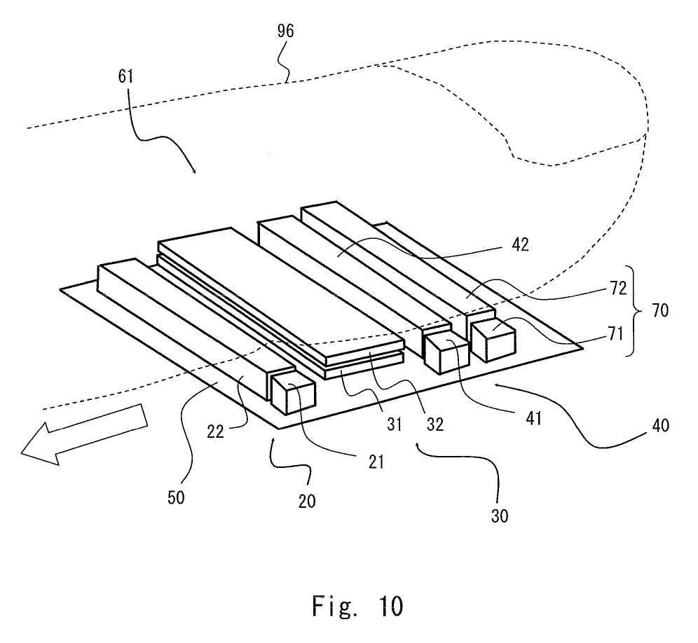

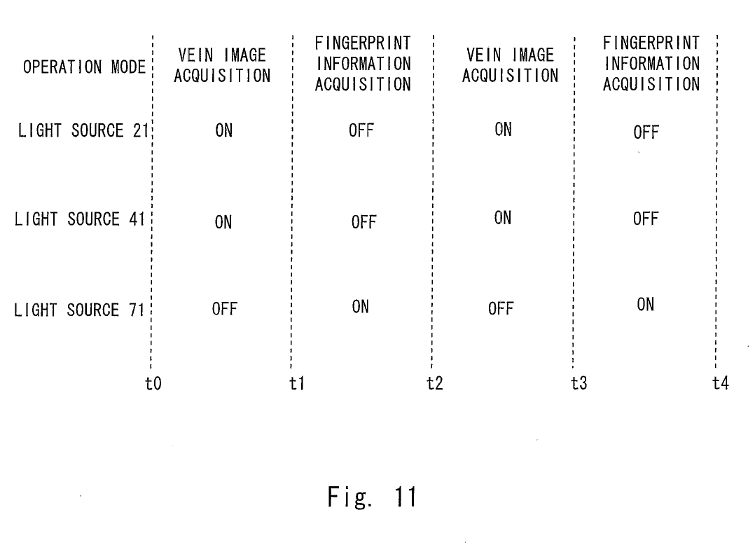

The configuration and the functions of a biometric information acquisition apparatus that is used for vein authentication are described hereinafter with reference to FIGS. 10 and 11.

A biometric information acquisition apparatus 61 according to a second embodiment of the present invention detects the movement of the fingerprint pattern of the finger 96 using an optical method. The biometric authentication apparatus 80 obtains the moving amount per unit time of the finger 96 and the moving direction of the finger 96 based on the detection result of the biometric information acquisition apparatus 61. In this case also, the same advantages as the first embodiment are obtained. Therefore, a means of detecting the movement of the fingerprint pattern of the finger 96 (the fingerprint detection unit) is not limited to the capacitance sensor, and it may be implemented using a line sensor for vein image acquisition.

As shown in FIG. 10, the biometric information acquisition apparatus 61 includes a light illumination unit 70. The light illumination unit 70 illuminates the finger 96 with light in the visible region. Pattern information (fingerprint information) reflecting the fingerprint image of the finger 96 can be thereby acquired by the image pickup device 31. Thus, the image pickup device 31 of this embodiment acquires pattern information reflecting a fingerprint image (which is referred to hereinafter simply as pattern information) in addition to vein images. Then, based on a plurality of pieces of pattern information acquired by the image pickup device 31, a vein image for authentication is formed from a plurality of vein images acquired by the image pickup device 31. The pattern information acquired by the image pickup device 31 is used to obtain the moving amount per unit time of the finger 96 and the moving direction of the finger 96.

The light illumination unit 70 includes a light source 71 and a light guide 72.

The light source 71 is a semiconductor optical device with a mold-packaged semiconductor chip such as a semiconductor light emitting diode (LED) or a semiconductor laser diode (LD). By applying a current between the electrodes, the light source 71 outputs light with a wavelength in the visible region (which is a wavelength of 360 nm to 830 nm, and it is 530 nm in this example).

The light guide 72 is a light guiding member that is substantially transparent to the output light from the light source 71. The light guide 72 has the same structure as the light guides 22 and 42. The light guide 72 guides the light from the light source 71 input through the side surface (light incident surface) to the top surface (light output surface) through a plurality of reflective surfaces formed on the bottom surface. Depending on a difference in the wavelength of light to be guided, the arrangement interval of the reflective surfaces formed on the light guide 72 may be different from that of the light guides 22 and 42.

The biometric information acquisition apparatus 61 operates as shown in FIG. 11.

During t0 and t1, the biometric information acquisition apparatus 61 is in vein image acquisition mode. In this period, near-infrared light is output from the light source 21 and the light source 41. The light output from each light source is applied to the finger 96 through each light guide. Then, the vein image in the range corresponding to the placement range of the pixels PX1 to PX8 is acquired by the image pickup device 31.

During t1 and t2, the biometric information acquisition apparatus 61 is in fingerprint information acquisition mode. In this period, visible light is output from the light source 71. The light output from the light source 71 is applied to the finger 96 through the light guide 72. Then, the pattern information (fingerprint information) reflecting the fingerprint image in the range corresponding to the placement range of the pixels PX1 to PX8 is acquired by the image pickup device 31.

The operation during t2 and t3 is the same as the operation during t0 and t1. The operation during t3 and t4 is the same as the operation during t1 and t2. Thus, repeated explanation is omitted.

The biometric information acquisition apparatus 61 repeats the vein image acquisition mode and the fingerprint information acquisition mode at very short time intervals.

When the image formation unit 83 forms a vein image for authentication from a plurality of vein images acquired by the image pickup device 31, it identifies the relative positions of the respective vein images acquired by the image pickup device 31 based on the plurality of pieces of pattern information acquired by the image pickup device 31. The operation of the image formation unit 83 is the same as that described in the first embodiment.

By obtaining the moving amount per unit time of the finger 96 and the moving direction of the finger 96 using the optical method as described above and then identifying the relative positions of the plurality of vein images based thereon, it is possible to generate one authentication image from a plurality of vein images regardless of the movement of the finger 96.

In this embodiment, the fingerprint detection unit 87 is composed of the light illumination unit 70 and the image acquisition unit 30. Further, when the image formation unit 83 forms a vein image for authentication from a plurality of vein images acquired by the image pickup device 31, it identifies the relative positions of the respective vein images acquired by the image pickup device 31 based on the plurality of pieces of pattern information reflecting the vein images acquired by the image pickup device 31.

Although the focal length of the lenses L1 to L8 is set according to vein images to be acquired, the pattern reflecting fingerprint image may be also acquired by the pixels PX1 to PX8.

### Third Embodiment

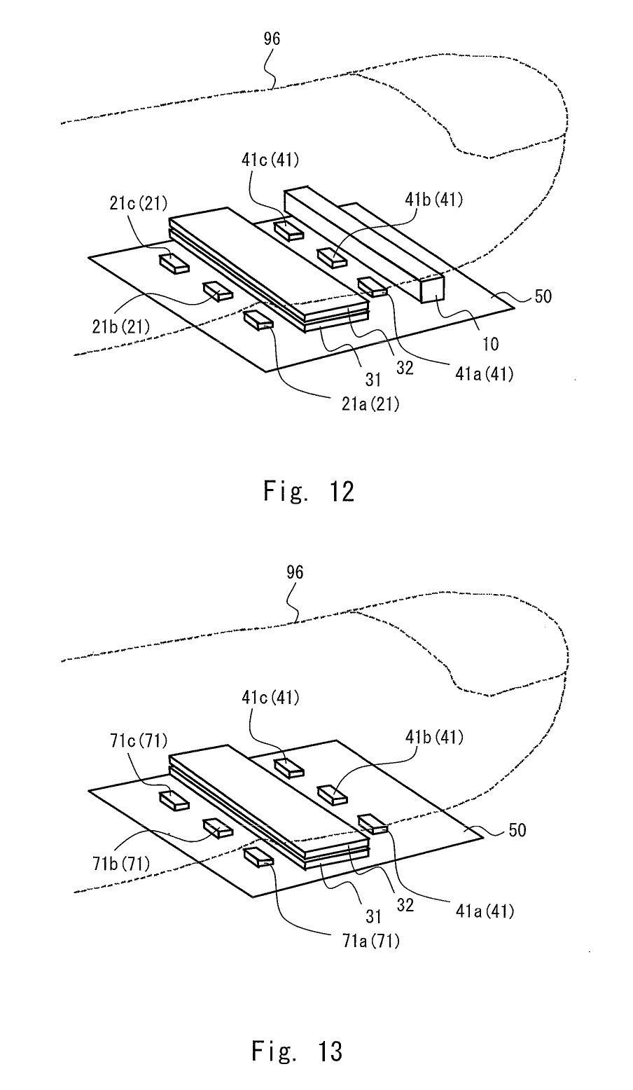

A biometric information acquisition apparatus according to a third embodiment of the present invention is described hereinafter with reference to FIG. 12.

In this embodiment, a plurality of light sources 21 are arranged along the pixel arrangement direction of the image pickup device 31, without using the light guide 22. Likewise, a plurality of light sources 41 are arranged along the pixel arrangement direction of the image pickup device 31, without using the light guide 42. In this case also, the same advantages as those described in the first embodiment are obtained. Thus, it is possible to illuminate a subject with light over a desired range without increasing the size of the biometric information acquisition apparatus 61.

The light sources 21 and 41 emit near-infrared light. Light sources 21a to 21c are arranged at substantially equal intervals. Likewise, light sources 41a to 41c are arranged at substantially equal intervals. By arranging the plurality of light sources 21 and 41 in this manner, it is possible to easily generate uniform light over the range corresponding to the pixel array of the image pickup device 31. The light sources 21a to 21c constitute a light illuminator. The light sources 41a to 41c also constitute a light illuminator.

### Fourth Embodiment

A biometric information acquisition apparatus according to a fourth embodiment of the present invention is described hereinafter with reference to FIG. 13.

In this embodiment, the light sources 71 that output visible light are placed instead of the light sources 21 of the third embodiment. In this case also, the same advantages as those described in the second embodiment are obtained.

Light sources 71a to 71c are arranged at substantially equal intervals. By arranging the plurality of light sources 71 in this manner, it is possible to easily generate uniform light over the range corresponding to the pixel array of the image pickup device 31. The light sources 71a to 71c constitute a light illuminator.

### Fifth Embodiment

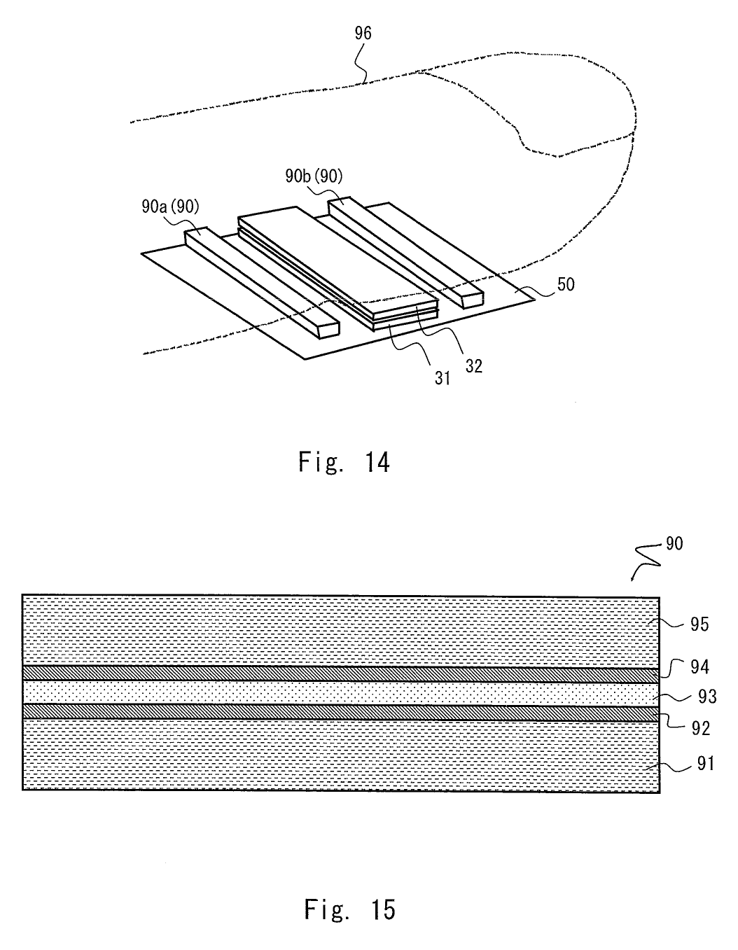

A biometric information acquisition apparatus according to a fifth embodiment of the present invention is described hereinafter with reference to FIGS. 14 and 15.

In this embodiment, an area light source 90 using electroluminescence is employed as a light illuminator. In this case also, the same advantages as those described in the first embodiment are obtained. In this example, two area light sources 90a and 90b are arranged with the image pickup device 31 placed therebetween.

The area light source 90 is a longitudinal member along the pixel arrangement direction of the image pickup device 31. The area light source 90 emits light by energization. The area light source 90 emits light within the range corresponding to the pixel array of the image pickup device 31. Specifically, the area light source 90 outputs light with a uniform intensity over the range corresponding to the pixel array of the image pickup device 31.

If the output light of the area light source 90 does not contain near-infrared light, a wavelength conversion filter is placed on the area light source 90. With utilization of the wavelength conversion filter, the area light source 90a may be used as a near-infrared light source, and the area light source 90b may be used as a visible light source. In this case, the same advantages as the second embodiment are obtained.

The schematic cross-sectional structure of the area light source 90 is described hereinafter with reference to FIG. 15. As shown in FIG. 15, the area light source 90 includes a transparent substrate 91, an electrode layer 92, an organic EL layer 93, an electrode layer 94, and a transparent substrate 95.

The transparent substrates 91 and 95 are transparent planar members such as glass. The electrode layers 92 and 94 are electrodes that are transparent to the output light from the organic EL layer 93. The electrode layers 92 and 94 may be patterned. The organic EL layer (organic light emitting layer) 93 is a layer in which an electron transport layer, a light emitting layer and a positive hole transport layer are sequentially placed on top of one another.

By applying a power between the pair of electrode layers 92 and 94, the energy state of organic molecules forming the light emitting layer makes a transition, so that light with a given wavelength is generated from the light emitting layer. The light generated by the light emitting layer is output to the front through the electrode layer 94 and the transparent substrate 95. The electrode layer 92 may have characteristics that reflect the light generated by the light emitting layer. Further, a reflective layer may be placed between the light emitting layer 93 and the transparent substrate 91. The thickness of each layer shown in FIG. 15 does not indicate an actual thickness.

### Sixth Embodiment

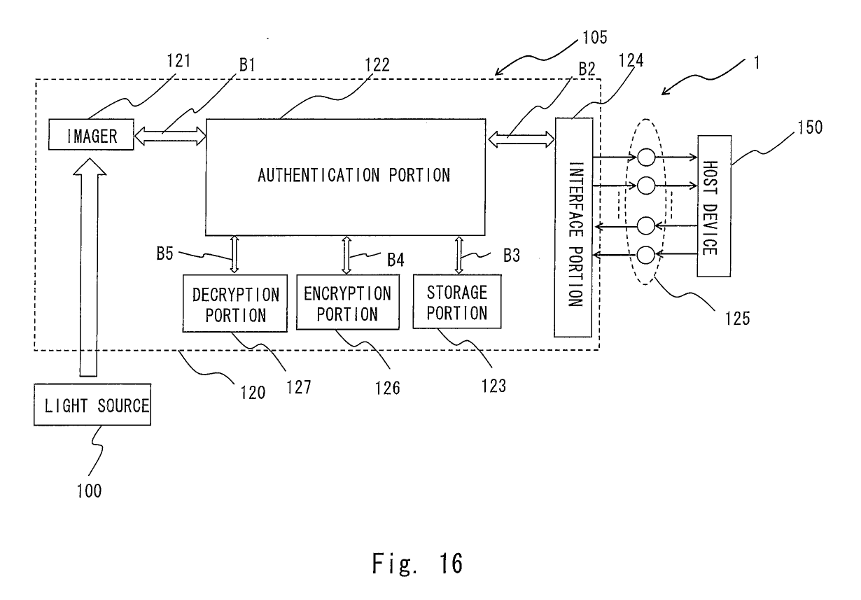

A sixth embodiment of the present invention is described hereinafter with reference to FIGS. 16 to 19.

The biometric authentication system disclosed in the patent document 3 is susceptible to hacking that acquires biometric information or analyzes an authentication algorithm by analyzing the data of the external bus during authentication.

A banking terminal such as an automated teller machine (ATM) involves a small number of end users, and a provider of a service can thus manage the machine safely, so that it has less risk of such hacking. On the other hand, a cellular phone, a personal computer (PC) and so on are used by a large number of end users, and it is thus difficult for a provider of a service to manage those machines so as to avoid hacking, and therefore it is susceptible to hacking. In such a case, it is extremely important to prevent hacking from taking place.

In light of the foregoing, an object of this embodiment is to ensure higher security in addition to, or in place of, the object described in the above embodiments.

As shown in FIG. 16, a biometric authentication system 1 includes a biometric authentication apparatus 105 and a host device 150. The biometric authentication apparatus 105 compares biometric information such as fingerprint patterns and finger vein patterns acquired from captured images with prestored biometric information to perform authentication. The host device 150 operates according to the authentication result that is output from the biometric authentication apparatus 105.

The biometric authentication apparatus 105 includes a light source 100 and a semiconductor device (biometrics integrated circuit (IC)) 120. The semiconductor device 120 is equivalent to the image pickup device 31 described in the above embodiments.

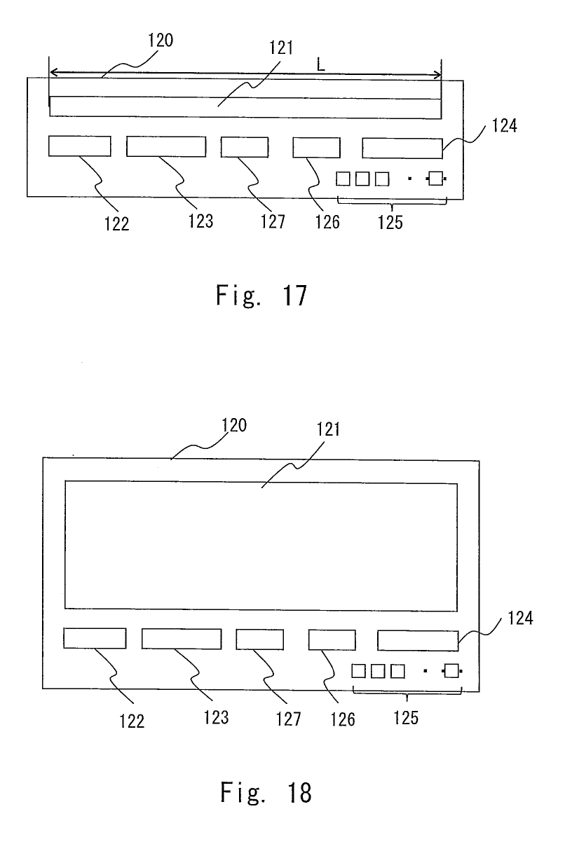

As shown in FIG. 16, the biometrics IC 120 includes an imager 121, an authentication portion 122, a storage portion 123, an interface portion 124, input/output terminals 125, an encryption portion 126, and a decryption portion 127. Corresponding to the functional portions shown in FIG. 16, the biometrics IC 120 includes an imaging region 121, an authentication region 122, a storage region 123, an interface region 124, an input/output terminal region 125, an encryption region 126 and a decryption region 127 as shown in FIG. 17. The biometrics IC 120 is a monolithic IC.

As shown n FIG. 16, the biometrics IC 120 includes internal buses B1 to B5. The internal bus B1 connects the imager 121 and the authentication portion 122. The internal bus B2 connects the authentication portion 122 and the interface portion 124. The internal bus B3 connects the authentication portion 122 and the storage portion 123. The internal bus B4 connects the authentication portion 122 and the encryption portion 126. The internal bus B5 connects the authentication portion 122 and the decryption portion 127. The internal buses function as signal transmission channels. The biometrics IC 120 has signal transmission regions corresponding to the internal buses.

This embodiment employs the above-described biometrics IC 120. It is thereby possible to perform acquisition and authentication of biometric information on the same chip, thus preventing the biometric information from being output to the outside. It is practically difficult to pull the data flowing through the internal bus from the outside. By prohibiting access to the imaging data from the outside, it is possible to ensure high security.

The light source 100 corresponds to the light source 21 or the light source 71. In this case also, the light guide 22, 42, 72 may be used as in the above-described embodiments. The light source 100 may be eliminated in the case of acquiring fingerprint patterns as biometric information.

The imager 121 includes one or more pixel arrays where a plurality of pixels are arranged. An optical functional portion (cf. FIG. 2C) is placed on top of the imager 121.

The imager 121 captures an image of a finger moving above an image pickup surface. Alternatively, the imager 121 may capture an image of a finger fixed in position while being slid. Further, an area sensor in which a plurality of pixels are arranged in matrix may be used as the imager 121 as shown in FIG. 18.

In the case of performing biometric authentication based on fingerprint patterns, an electrostatic sensor that detects electrical charges according to the projections and recesses of a finger may be used as the imager 121. Alternatively, a thermal sensor that detects a temperature difference in the projections and recesses of a finger may be used. In either case, fingerprint patterns can be acquired by each sensor. The imager 121 is preferably a complementary metal-oxide semiconductor (CMOS) image sensor in terms of semiconductor device manufacturing process.

A bandpass filter (optical functional portion) is placed on the imager 121. The mechanism that the imager 121 captures vein images or fingerprint images is the same as that described in the above embodiments. The imager 121 outputs a signal generated by imaging to the authentication portion 122 through the internal bus B1.

The authentication portion 122 performs analog-to-digital conversion, binarization and so on of the signal supplied from the imager 121 and acquires biometric information. Further, the authentication portion 122 compares the biometric information with prestored biometric information to perform authentication.

When the authentication portion 122 receives an authentication command from the host device 150, it controls the imager 121 and acquires biometric information. Then, the authentication portion 122 compares the acquired biometric information with the biometric information prestored in the storage portion 123 to perform authentication. The authentication command is transferred from the host device 150 to the authentication portion 122 through the interface portion 124 and the internal bus B2. The data captured by the imager 121 is transferred from the imager 121 to the authentication portion 122 through the internal bus B1. Authentication data to be used as master data is transferred from the storage portion 123 to the authentication portion 122 through the internal bus B3.

The storage portion 123 stores data captured by the imager 121 as master data. When the authentication portion 122 receives a registration command form the host apparatus 150, it controls the imager 121 to acquire data and registers the data into the storage portion 123.

The authentication portion 122 outputs a signal (information) indicating an authentication result to the host device 150 through the internal bus B2 and the interface portion 124.

The authentication portion 122 preferably encrypts the signal indicating an authentication result and then outputs it to the host device 150. As described earlier, the biometrics IC 120 includes the encryption portion 126 that encrypts the signal indicating an authentication result. The encryption portion 126 and the authentication portion 122 are connected through the internal bus B4. The encryption portion 126 executes encryption of the signal that is supplied from the authentication portion 122 through the internal bus B4. The encryption portion 126 then outputs the encrypted signal to the authentication portion 122 through the internal bus B4. The encrypted signal is transferred from the authentication portion 122 to the host device 150 through the internal bus B2 and the interface portion 124. By encrypting the signal to be output to the outside, it is possible to further enhance security. Specifically, it is possible to achieve high tamper resistance (resistance to leakage of internal information to the outside) and high security against hacking.

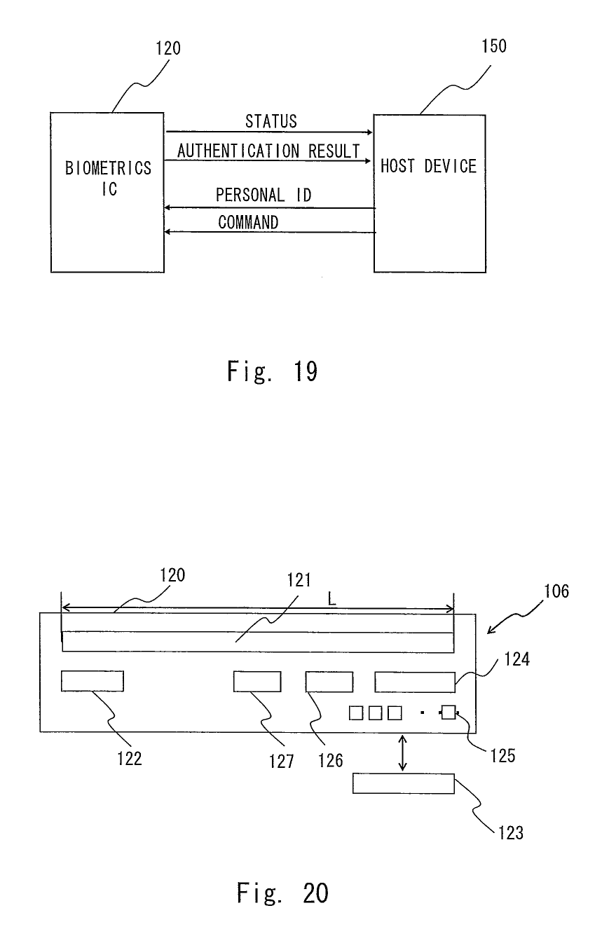

As shown in FIG. 19, when the authentication portion 122 receives a request command for an internal status of the biometrics IC 120 from the host device 150, it outputs a signal indicating the internal status of the biometrics IC 120. At this time also, the authentication portion 122 preferably encrypts the internal information signal of the biometrics IC 120 using the encryption portion 126 and then outputs it to the host device 150.

The storage portion 123 may be battery-backupable memory, rewritable nonvolatile memory or the like. The storage portion 123 stores registered biometric information, a program for implementing biometric information, a program for implementing image formation, an internal status of the biometrics IC 120 and so on.

The storage portion 123 may store biometric information of a plurality of persons. In this case, the biometric information of a person to be authenticated is selectable by a personal ID. Thus, a personal ID is assigned to each one of biometric information. After an authentication command and a signal indicating a personal ID are transferred from the host device 150 to the authentication portion 122 as shown in FIG. 19, the authentication portion 122 reads the biometric information corresponding to the received personal ID from the storage portion 123 and performs authentication using the biometric information.

The host device 150 preferably encrypts the authentication command and the signal indicating a personal ID and outputs them. The biometrics IC 120 includes the decryption portion 127 that decrypts the encrypted authentication command and the encrypted signal indicating a personal ID. The decryption portion 127 and the authentication portion 122 are connected through the internal bus B5. The encrypted signal that is output from the host device 150 is input to the authentication portion 122 through the interface portion 124 and the internal bus B2. The encrypted information is then supplied from the authentication portion 122 to the decryption portion 127 through the internal bus B5 and decrypted by the decryption portion 127. The decrypted information is transferred from the decryption portion 127 to the authentication portion 122 through the internal bus B5. This enhances security against information leakage.

In the case where the storage portion 123 stores a plurality of pieces of biometric information, the acquired biometric information may be sequentially compared with the plurality of pieces of stored biometric information. This eliminates the need for a user to select a person upon authentication in the host device 150, thereby improving user-friendliness.

The host device 150 is a cellular phone, a PC or the like that incorporates the biometric authentication apparatus 105, for example. The host device 150 and the biometrics IC 120 are connected to each other with their connectors coupled to each other. The host device 150 outputs a command indicating start or stop of authentication and a command indicating registration of biometric authentication, and, if needed, a command requesting the internal status of the biometrics IC 120 and a signal indicating a personal ID, to the biometrics IC 120. The host device 150 receives the signal indicating an authentication result from the biometrics IC 120 and, when the authentication result matches the biometric information of the identical person, for example, turns on the main power.

The biometrics IC according to the embodiment includes the imager 121, the authentication portion 122, the storage portion 123, the interface portion 124, the input/output terminals 125, the encryption portion 126 and the decryption portion 127. Those functional portions are placed on the same surface (the top surface in FIG. 16) of a monolithic chip.

Further, it is preferred to place the authentication portion 122, the storage portion 123, the interface portion 124, the input/output terminals 125, the encryption portion 126 and the decryption portion 127 within a region L with the same width as the imager 121. This effectively suppresses an increase in chip size.

### Seventh Embodiment

A seventh embodiment of the present invention is described hereinafter with reference to FIG. 20.

In a biometric authentication apparatus 106 according to the embodiment, the storage portion 123 is not placed on the biometrics IC 120, which is different from the sixth embodiment. The biometric authentication apparatus 106 according to the embodiment encrypts the data to be stored in the storage portion 123 and stores it into an external apparatus (e.g. the host device). In this case, the authentication portion 122 transfers the biometric information acquired by controlling the imager 121 to the encryption portion 126, and then transfers the information encrypted by the encryption portion 126 to the external storage portion 123. At the time of executing authentication, the authentication portion 122 makes control so that the encrypted information stored in the external storage portion 123 is transferred to the decryption portion 127. The authentication portion 122 executes authentication using the information decrypted by the decryption portion 127.

In the case where a large number of users share the biometric authentication apparatus, the memory capacity of the storage portion 123 increases, which makes it difficult to place the storage portion 123 on the same chip as the imager 121. In light of this, the storage portion 123 is placed externally, and encrypted data is transferred to the storage portion 123 in this embodiment. This allows a large number of users to share the biometric authentication apparatus. Further, this ensures high security just like the above-described embodiments. Specifically, it is possible to ensure high tamper resistance and high security against hacking.

It is preferred to place the imager 121, the authentication portion 122, the interface portion 124, the input/output terminals 125, the encryption portion 126 and the decryption portion 127 on the same surface (the top surface in FIG. 20) of the chip. Further, it is preferred to arrange them with their top ends at a substantially equal height.

### Eighth Embodiment

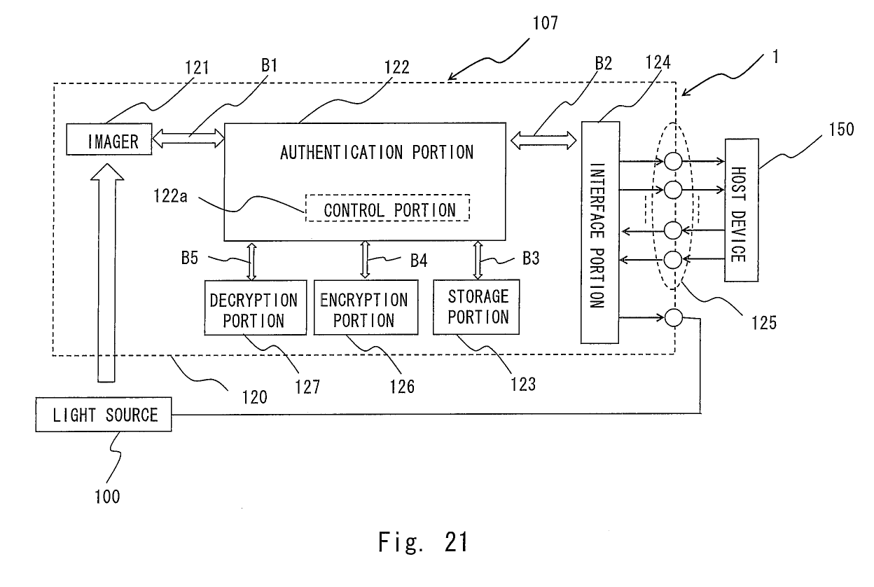

An eighth embodiment of the present invention is described hereinafter with reference to FIG. 21.

In a biometric authentication apparatus 107 according to the embodiment, the authentication portion 122 includes a control portion 122a that controls the illumination intensity of the light source 100 that illuminates a subject with light, which is different from the sixth embodiment. The control portion 122a controls the illumination intensity of the light source 100 in such a way that a signal (e.g. a signal voltage) output form the imager 121 has an optimum signal level. Specifically, the control portion 122a makes control so as to increase the illumination intensity of the light source 100 when an output level of the imager 121 is low. On the other hand, the control portion 122a makes control so as to decrease the illumination intensity of the light source 100 when an output level of the imager 121 is high. It is thereby possible to reduce variations of the brightness of acquired biometric information.

### Ninth Embodiment

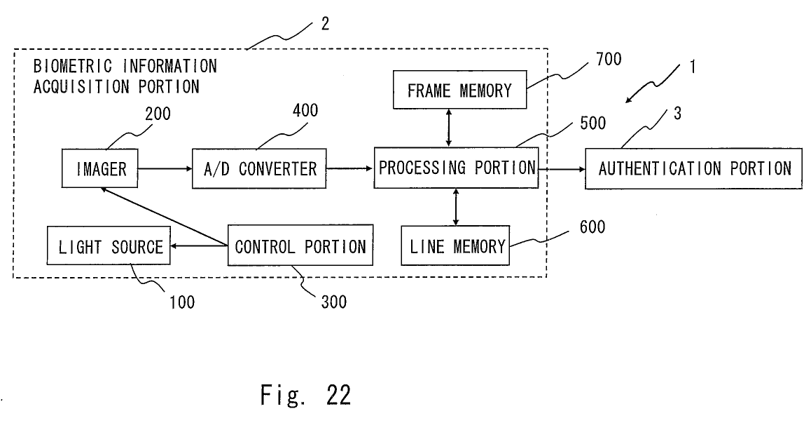

A ninth embodiment of the present invention is described hereinafter with reference to FIGS. 22 to 28.

The biometric information acquisition apparatus according to the patent document 4 needs to have a space for moving the sliding member including the line sensor below a subject. Likewise, the biometric information acquisition apparatus according to the patent document 4 needs to have a space for containing the driver or the like.

An object of this embodiment is to capture a desired image with a smaller space in addition to, or in place of, the object described in the above embodiments.

The biometric authentication system 1 includes a biometric information acquisition portion (biometric information acquisition apparatus) 2 and an authentication portion 3. The biometric information acquisition portion 2 acquires images of a subject and acquires biometric information such as fingerprint patterns and finger vein patterns. The authentication portion 3 performs authentication by comparing the biometric information acquired by the biometric information acquisition portion 2 with the prestored biometric information. The biometric authentication system 1 is suitably incorporated into a cellular phone, a PC, an ATM or the like, which is electronic equipment.

The biometric information acquisition portion 2 includes a light source 100, an imager 200, a control portion 300, an analog/digital (A/D) converter 400, a processing portion 500, a line memory 600 and a frame memory 700.

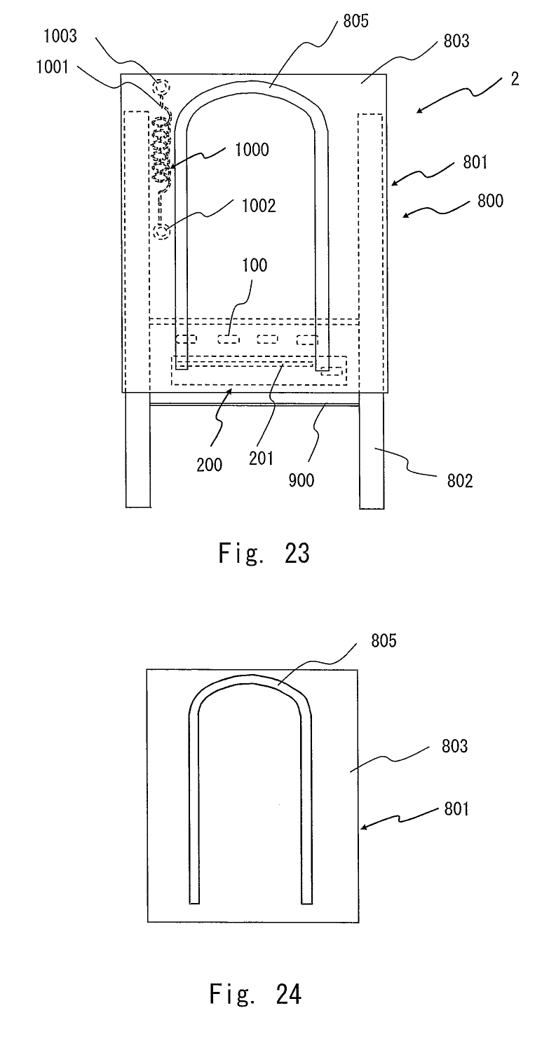

The biometric information acquisition portion 2 includes a moving mechanism 800 as shown in FIGS. 23 to 26. The movement of a finger, which is a subject, is guided by the moving mechanism 800. Specifically, the finger is guided by the moving mechanism 800 and moves in the direction intersecting with the pixel arrangement direction of a line sensor 201. The line sensor 201 acquires images at different timings in the process of moving the finger. The images of a desired number of lines are thereby captured, and one authentication image can be created from those images.

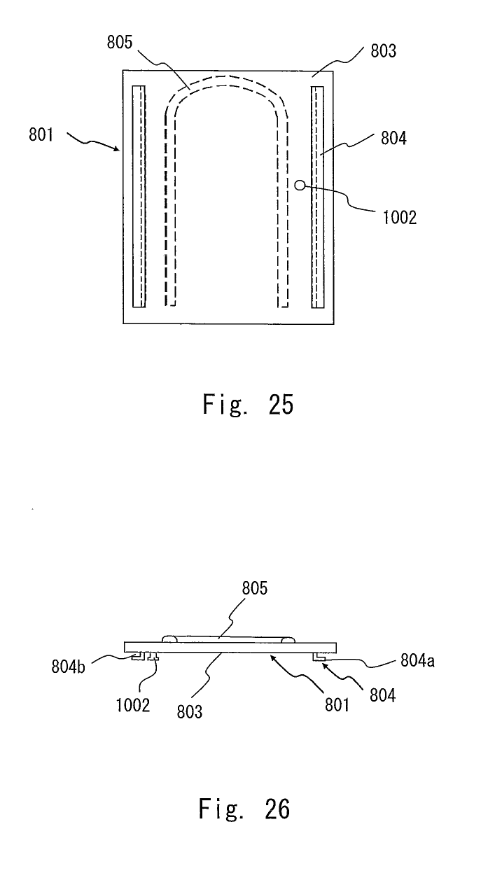

The moving mechanism 800 includes a placing table 801 and a guiding member 802. The placing table 801 is a planar member having transparency to light applied to the finger from the light source 100 (which is referred to hereinafter simply as inspection light) as shown in FIG. 24. The placing table 801 includes a placing portion 803 having a size that allows placement of at least a given part of the finger to be imaged. On the bottom surface of the placing portion 803, two L-shaped members 804 are placed as shown in FIGS. 25 and 26. The L-shaped members 804 are placed in parallel with the direction of the finger, at both ends of the imaging region of the finger. The L-shaped member 804 has a horizontal piece 804a projecting outward. On the top surface of the placing portion 803, a reverse U-shaped position regulating member 805 outlining the periphery of the finger is placed. The position to place the finger is regulated by the position regulating member 805. A user's finger is thereby placed on a predetermined position, so that highly accurate images can be captured.

The guiding member 802 may have a horizontal piece that can fit into a groove portion 804b of the L-shaped member 804. The guiding member 802 is an L-shaped member or a squared U-shaped member, for example. The length of the guiding member 802 is longer than the length of a given part of the finger to be placed on the placing portion 803. The horizontal piece of the guiding member 802 fits into the groove portion 804b of the L-shaped member 804. The guiding member 802 may be fixed to the housing of a cellular phone, for example.

A casing member 900 is placed between the two guiding members 802. The both ends of the casing member 900 are fixed to the guiding members 802.

The casing member 900 contains the plurality of light sources 100 and the imager 200. In the casing member 900, the arrangement direction of the plurality of light sources 100 is substantially parallel to the pixel arrangement direction of the line sensor 201. The guiding member 802 regulates the moving direction of the placing table 801. The longitudinal direction of the line sensor 201 coincides with the direction intersecting with the moving direction of the placing table 801.

A user puts the finger on the substantially planar placing table 801 placed above the light sources 100 and the line sensor 201. Next, the user manually slides the placing table 801 in the direction intersecting with the pixel arrangement direction of the line sensor 201 (downward on the sheet). A given part of the finger placed on the placing table 801 passes across the line sensor 201. The imager 200 sequentially captures images within the sliding region of the placing table 801. In this embodiment, the placing table 801 that operates manually is used. In this case, there is no need to make a space for moving the line sensor, which is an imaging component, and a space for containing a driver. Further, there is no need to have a driving source for moving the sliding member. This enables acquisition of images with a smaller space without a driving source compared to related art. This also allows use of a line sensor, which is less expensive than an area sensor. Further, this permits effective use of the space below the placing table 801 by placing an electronic component or the like. It is thereby possible to reduce the size of electronic equipment that incorporates the biometric authentication system 1.

The light source 100 is a semiconductor light emitting diode (LED), a semiconductor laser diode (LD) or the like. The biometric information acquisition portion 2 applies inspection light to the finger placed on the placing portion 803 by driving the light source 100. The inspection light is visible light (with a wavelength of about 360 to 800 nm) or near-infrared light (with a wavelength of about 0.7 to 2.5 μm). The inspection light may be applied to the finger directly from a LED or the like or indirectly using a light guide or the like. Further, the light source may be eliminated in the case of acquiring fingerprint patterns as biometric information.

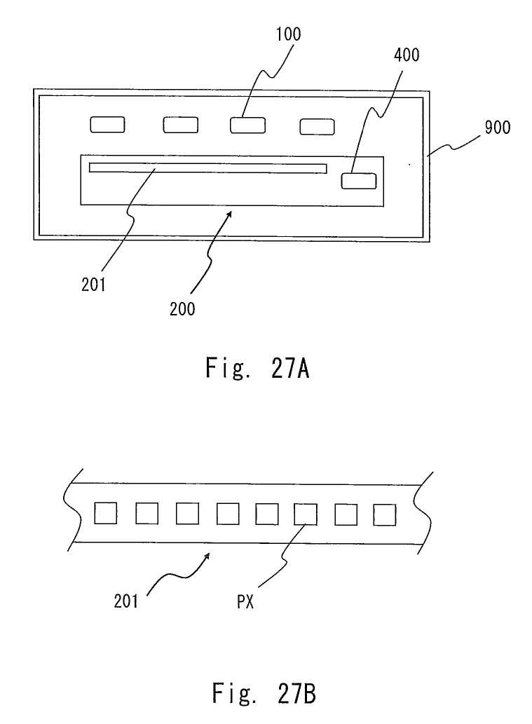

Reflected light or transmitted light from the finger enters the imager 200 through the placing portion 803. The imager 200 is a complex element in which an optical functional portion is placed on top of the line sensor 201. The line sensor 201 includes a plurality of pixels arranged in a row as shown in FIG. 27B. Alternatively, an area sensor that includes a plurality of pixels arranged in matrix may be used.

The reflected light or transmitted light from the finger which is input from above passes through a bandpass filter (optical functional portion) that shields external disturbance light. Then, the input light is focused on each pixel PX of the line sensor 201 by a microlens array (optical functional portion) The imager 200 then photoelectrically converts the input light in each pixel PX, reads a signal from each pixel PX and supplies it to the A/D converter 400.

The light source 100 and the imager 200 are controlled by the control portion 300. The control portion 300 directs the light source 100 and the imager 200 to start or stop operation, for example. For instance, the control portion 300 controls the imager 200 to output imaging data at a given read timing. The control portion 300 controls the biometric information acquisition portion 2 as a whole.

The A/D converter 400 converts the output signal from each pixel PX form analog to digital and supplies the result to the processing portion 500. The processing portion 500 sequentially writes the supplied signals into the line memory 600. The line memory 600 accumulates the supplied signals from the respective pixels PX. When signals for one pixel array (a line signal) are accumulated, the line memory 600 supplies the line signal to the frame memory 700 through the processing portion 500. The frame memory 700 accumulates the supplied line signals. When a desired number of line signals (which forms a desired image) are accumulated, the frame memory 700 supplies the desired number of line signals to the processing portion 500. The processing portion 500 performs binarization or the like on the desired number of supplied line signals.

The image data acquired by the biometric information acquisition portion 2 is supplied from the processing portion 500 to the authentication portion 3. The authentication portion 3 compares the acquired biometric information with the prestored biometric information to perform authentication.

The biometric information acquisition portion 2 preferably includes a returning mechanism 1000 that returns the placing table 801 to its original position as shown in FIG. 23. For example, an elastic body 1001 such as a spring is placed in parallel to the longitudinal direction of the guiding member 802. One end of the elastic body 1001 is coupled to a coupling piece 1002 placed on the bottom surface of the placing portion 803. The other end of the elastic body 1001 is coupled to a coupling piece 1003 placed on the housing of a cellular phone or the like. By placing the returning mechanism 1000, user-friendliness is improved. Specifically, the returning mechanism 1000 eliminates the need for a user to manually return the placing table 801 to the original position (the initial position of the placing table 801). Further, the returning mechanism 1000 allows the placing table 801 to return to its original position with high accuracy, thereby improving the quality of images to be captured next.

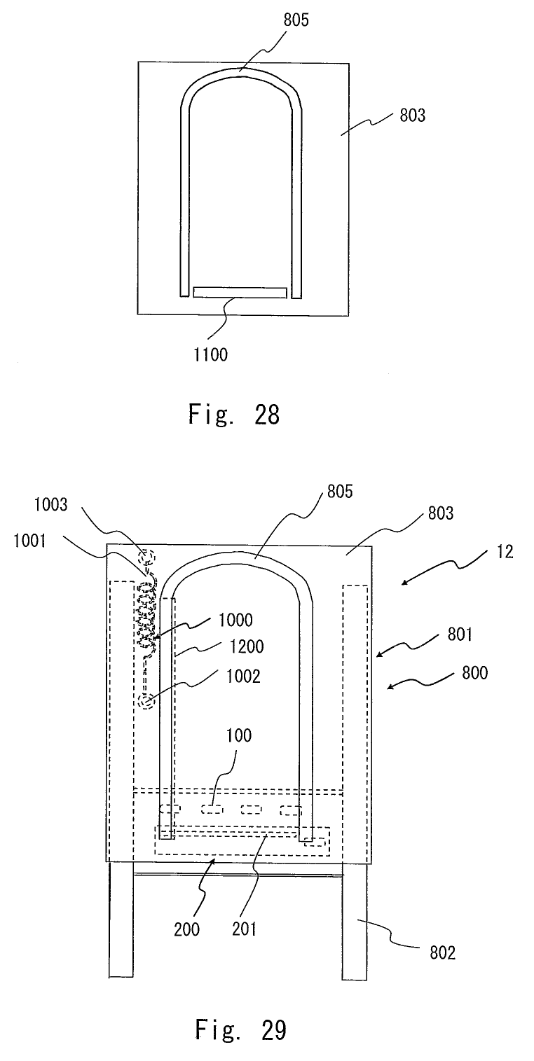

Further, it is preferred to place a nonslip member 1100 made of resin or the like on the top surface of the placing portion 803 as shown in FIG. 28. The nonslip member 1100 is located at the lower end of the position regulating member 805. The nonslip member 1100 may be placed in any position as long as it does not affect imaging. Further, the nonslip member 1100 is not limited to resin or the like as long as it is a member that increases resistance with the finger.

### Tenth Embodiment

A tenth embodiment of the present invention is described hereinafter with reference to FIGS. 29 to 33.

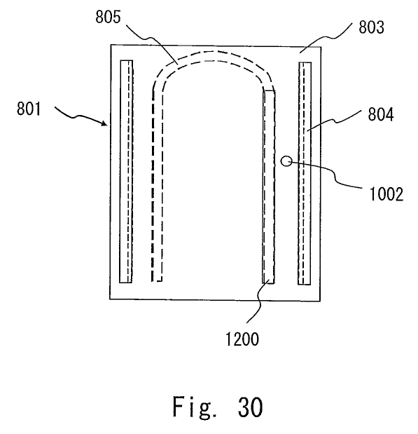

A biometric information acquisition portion 12 has a regular pattern 1200 above the line sensor 201 as shown in FIGS. 29 and 30. The pattern 1200 enables detection of the moving amount of the placing table 801 with respect to the line sensor 201.

The line sensor 201 includes a pixel for capturing an image of a finger and a pixel for detecting a pattern. The pattern 1200 is placed above the pattern detection pixel. The movement of the pattern is detected by the pattern detection pixel. The pattern 1200 is formed substantially parallel to the moving direction of the finger.

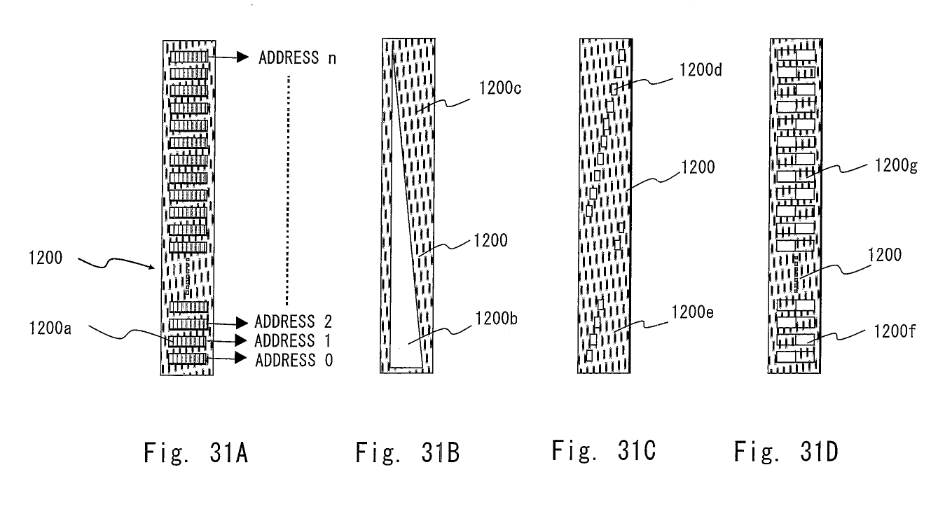

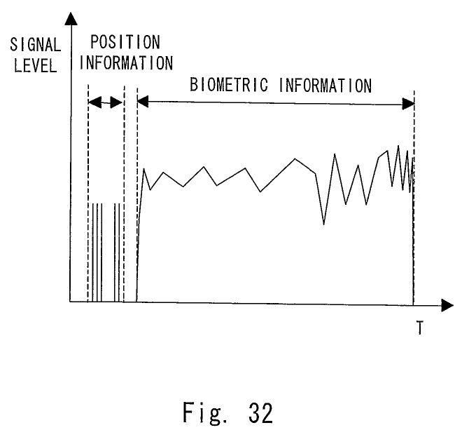

The pattern 1200 has an address code 1200a illustrated in FIGS. 31A so as to add position information (address) to the image captured by the line sensor 201. The pattern 1200 is formed in advance on the bottom surface of the placing portion 803. With the pattern 1200, it is possible to specify the position of the acquired image data.

The pattern 1200 moves as the placing portion 803 moves. The imager 200 captures the image of the address code 1200a at the same time as capturing the image of the finger, thereby acquiring position information. It is thereby possible to acquire the position information of image data in addition to the image data acquired at certain timing. The relative positions of the respective image data are thereby obtained. Based on the relative positions of the respective image data, one authentication image can be created from the plurality of image data. The line sensor repeats the image pickup operation at sufficiently short time intervals.

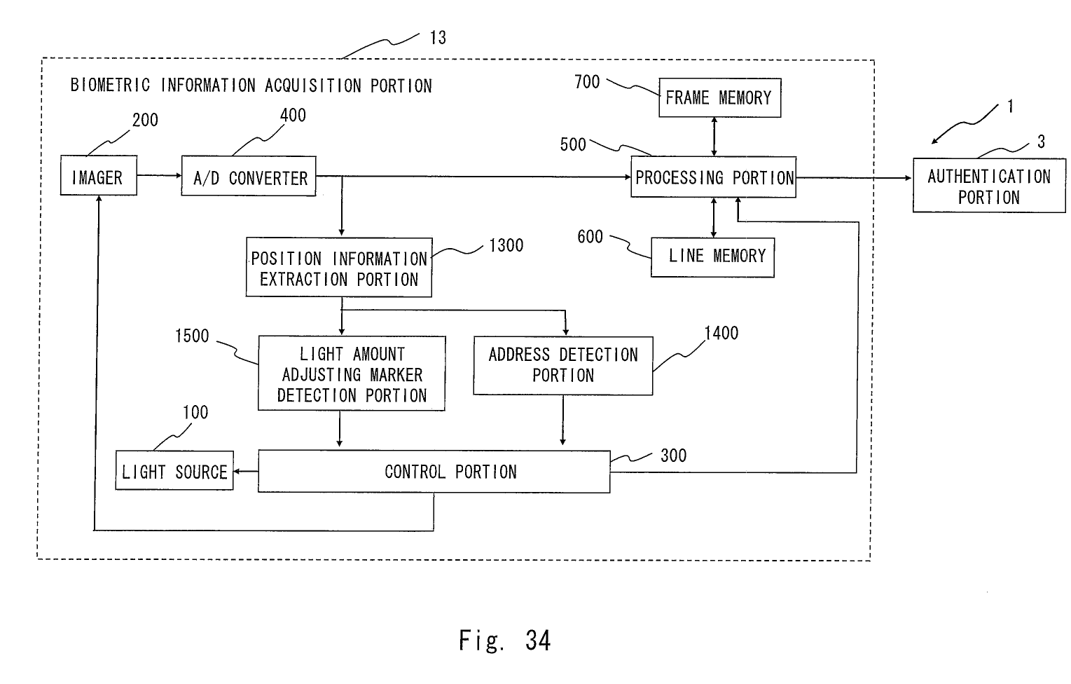

The imager 200 reads the position information obtained by the address code 1200a and the imaging data of the finger in association with each other. As shown in FIG. 33, a position information extraction portion 1300 extracts the position information obtained by the address code 1200a.

The position information extraction portion 1300 supplies the imaging data of the address code 1200a to an address detection portion 1400. The address detection portion 1400 detects an address based on the supplied data. The address detection portion 1400 supplies a signal indicating the address to the processing portion 500 through the control portion 300. The output of the pattern detection pixel may be converted from analog to digital and then directly connected to the address detection portion 1400 without through the position information extraction portion 1300.

On the other hand, the imaging data of the finger is accumulated in the line memory 600 through the processing portion 500. The line memory 600 supplies the accumulated line signals obtained by capturing images of the finger to the processing portion 500.

The processing portion 500 associates the supplied position information with the imaging data of the finger and supplies them to the frame memory 700. With the movement of the placing table 801, the position information and the imaging data of the finger supplied from the processing portion 500 are associated and sequentially supplied to the frame memory 700. The frame memory 700 is configured to arrange the line signals obtained by capturing images of the finger based on the position information. The frame memory 700 arranges the line signals obtained by capturing images of the finger based on the supplied position information and thereby creates one desired composite image. In this manner, one desired composite image can be created with high accuracy from one row of image data output from the line sensor 201.

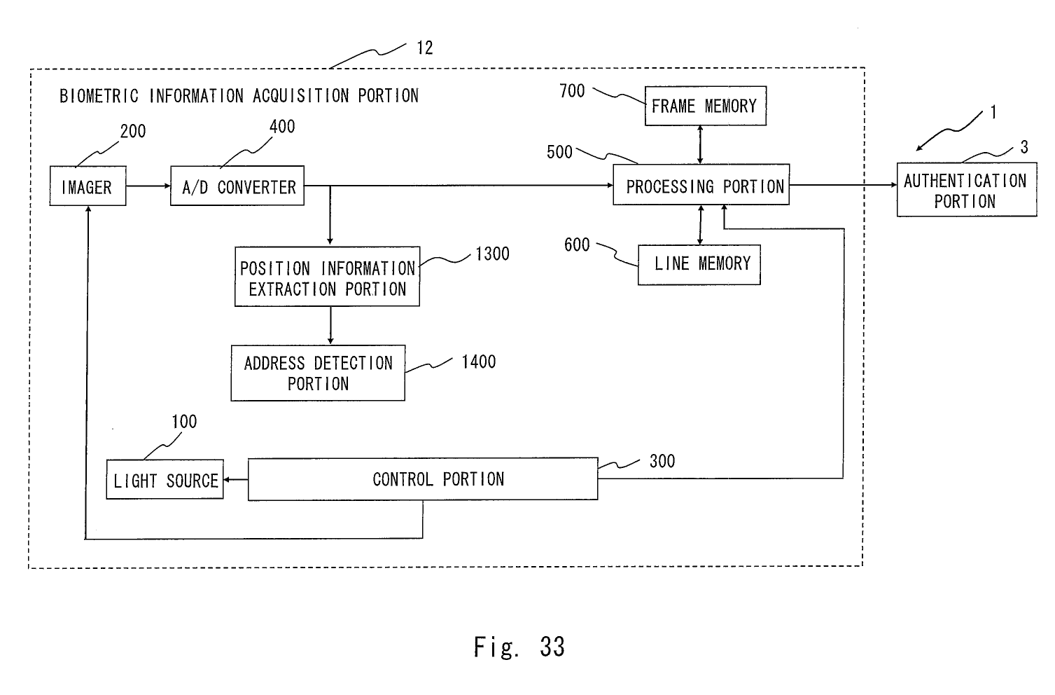

In this embodiment, the imager 200 reads the signal obtained by capturing images of the address code 1200a in advance as shown in FIG. 32. However, the imager 200 may read the line signal obtained by capturing images of the finger in advance and then read the signal obtained by capturing the image of the address code 1200a after that. The reading of the signals is regulated by the control of a vertical scanning circuit and a horizontal scanning circuit of the imager 200.

The pattern 1200 may have a triangular light reflecting portion 1200b and a light absorbing portion 1200c in a black region (which is a shaded area in the illustration) as shown in FIG. 31B. If data obtained when the line sensor 201 captures an image of the light reflecting portion 1200b is binarized by the address detection portion 1400, a signal pulse having a certain length is obtained. The address detection portion 1400 counts the number of pixels of the line sensor 201 corresponding to the length of the signal pulse and detects the address of the line signal obtained by capturing images of the finger.

Further, the pattern 1200 may have a light reflecting portion 1200d in which rectangular white spots each having substantially the same height as the length of one side of the pixel of the line sensor 201 are arranged on an N-line and a light absorbing portion 1200e in a black region (which is a shaded area in the illustration) different from the light reflecting portion as shown in FIG. 31C. In this case, if a signal obtained when the line sensor 201 captures an image of the white spots is binarized by the address detection portion 1400, a signal pulse corresponding to the arrangement of the white spots is obtained. The address detection portion 1400 detects the address of the line signal obtained by capturing images of the finger based on the position of the signal pulse. By arranging the white spots on the N-line as shown in FIG. 31C, the shift amount between the white spots adjacent vertically is large, thereby facilitating detection of the address of the line signal obtained by capturing images of the finger.

Furthermore, the pattern 1200 may have a light reflecting portion 1200f in a region of white blocks each having substantially the same height as the length of one side of the pixel of the line sensor 201 and a light absorbing portion 1200g in a region of black blocks (which is a shaded area in the illustration) which are arranged in an alternate manner per line (in a checkered pattern) as shown in FIG. 31D. In this case, the address detection portion 1400 counts the number of times when the light reflecting portion 1200f and the light absorbing portion 1200g are switched in turn, thereby detecting the address of the line signal obtained by capturing images of the finger.

The patterns 1200 of FIGS. 31A to 31D are shown by way of illustration, and any pattern may be used as long as it can detect the address.

Further, a detecting means of the moving amount of the placing table 801 with respect to the line sensor 201 is not limited to the above-described pattern. For example, the moving amount of the placing table 801 with respect to the line sensor 201 may be detected using a means of detecting the moving amount such as an encoder. Thus, the detecting means may have any structure as long as it can detect the moving amount of the placing table 801 with respect to the line sensor 201.

### Eleventh Embodiment

An eleventh embodiment of the present invention is described hereinafter with reference to FIGS. 34 to 36.

A biometric information acquisition portion 13 according to this embodiment controls the amount of output light from the light source 100.

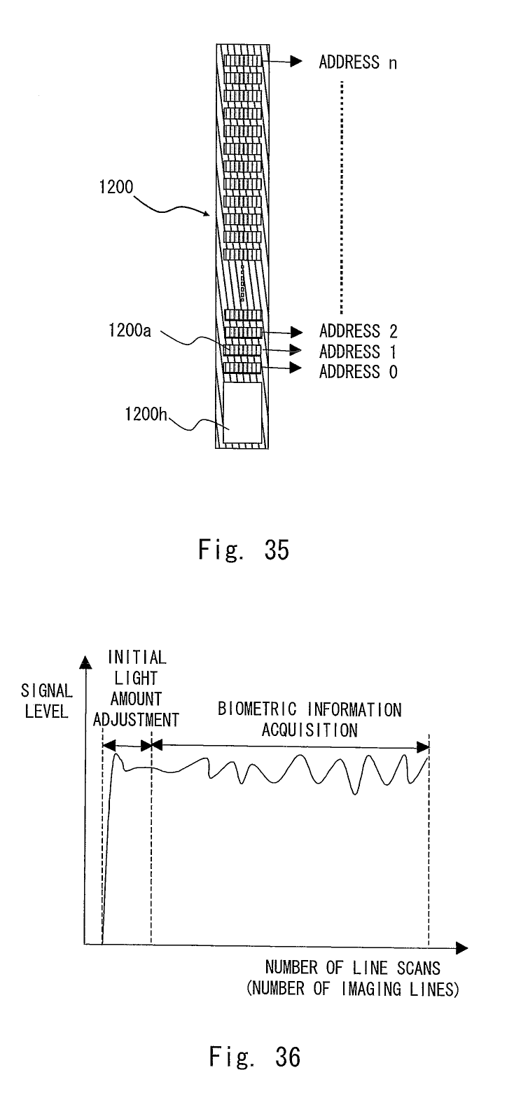

Specifically, the pattern 1200 has a light amount adjusting marker 1200h as shown in FIG. 35. The pattern 1200 is formed on the bottom surface of the placing portion 803. The light amount adjusting marker 1200h is a gray vertically-oriented region, for example. The light amount adjusting marker 1200h is formed on the front of the address code and the light reflecting portion so as to adjust the initial light amount of the light source 100.

As the placing portion 803 moves, the pattern 1200 having the light amount adjusting marker 1200h moves. Like the address code and the light reflecting portion described above, an image of the light amount adjusting marker 1200h is captured by the imager 200 and then extracted by the position information extraction portion 1300.

The position information extraction portion 1300 supplies the signal obtained by capturing the image of the light amount adjusting marker 1200h to the address detection portion 1400 and a light amount adjusting marker detection portion 1500. The light amount adjusting marker 1200h has a shape of a vertically-oriented block with an equal width. Thus, a continuous long signal pulse, which is different from the address code and the light reflecting portion described above, is supplied to the address detection portion 1400 and the light amount adjusting marker detection portion 1500. The address detection portion 1400 thereby recognizes that the supplied signal is not a signal for address detection. The light amount adjusting marker detection portion 150 recognizes that the supplied signal is a signal for light amount adjustment.

The light amount adjusting marker 1200h is gray. Thus, the light amount adjusting marker detection portion 1500 may recognize that the supplied signal is a signal for light amount adjustment when a signal indicating a gray level is supplied continuously.

The light amount adjusting marker detection portion 1500 supplies the signal obtained by capturing the image of the light amount adjusting marker 1200h to the control portion 300. The control portion 300 is configured to determine the light amount of the light source 100 in such a way that the signal level of the signal obtained by imaging becomes an optimum signal level based on a prescribed relational expression. The relational expression represents the relationship between the signal level of a signal obtained by imaging in advance and the light amount of the light source 100.

When the signal obtained by capturing the image of the light amount adjusting marker 1200h is supplied, the control portion 300 determines the initial light amount of the light source 100 in such a way that the signal has an optimum signal level. The control portion 300 controls the light source 100 based on the determined initial light amount. In this state, the imager 200 captures images of the finger. Then, the imager 200 reads the imaging data obtained by capturing images of the finger and the information obtained by capturing images of the address code or the light reflecting portion.

The position information extraction portion 1300 extracts the information read as described above and supplies the extracted information to the address detection portion 1400 and the light amount adjusting marker detection portion 1500. Because a signal different from the signal obtained by capturing the image of the light amount adjusting marker 1200h is supplied, the light amount adjusting marker detection portion 1500 recognizes that it is not a signal for light amount adjustment. The address detection portion 1400 recognizes that it is a signal for address detection.

The address detection portion 1400 extracts an address based on the above information and supplies a signal indicating the address to the control portion 300.

The imaging data output from the line sensor is supplied to the line memory 600 and the control portion 300 through the processing portion 500. The control portion 300 determines a signal level of the imaging data. Based on the signal level, the control portion 300 controls the light source 100 so as to maintain the signal level of imaging data to be acquired by the next imaging operation to an appropriate value. Specifically, the control portion 300 controls the light source 100 so as to emit the determined light amount. The control portion 300 then controls the imager 200 to output a signal obtained by the next imaging.

The control portion 300 supplies the information indicating an address to the processing portion 500. On the other hand, the line memory 600 supplies the stored imaging data to the processing portion 500. The processing portion 500 associates the address information with the imaging data and supplies them to the frame memory 700.

The biometric information acquisition portion 13 repeatedly makes control in such a way that the level of an output to be acquired by the next imaging becomes an optimum value. The light source 100 is controlled to emit an optimum light amount at the next imaging. By a change in the intensity of outside light, a change in the moving speed of the placing table 801 or the like, it is possible to deal with a change in the amount of light input to the line sensor. FIG. 36 shows a signal obtained when the imager 200 captures images of the pattern 1200 and the finger while controlling the light amount of the light source 100.

The above-described embodiments may be combined as appropriate. The semiconductor device 120 is applicable to the other embodiments. Further, the moving mechanism 800 may be applied to the other embodiments (the first embodiment, the sixth embodiment etc.).

A specific structure of the light illuminator is arbitrary. The biometric information acquisition apparatus may be applied to the biometric authentication apparatus that executes fingerprint authentication in addition to vein authentication. Equipment into which the biometric authentication apparatus is incorporated may be installation equipment in addition to a cellular phone, a laptop PC or the like. The subject is not limited to a human finger, and it may be another part of a human body such as a human palm. The image pickup device maybe a general image pickup device including a plurality of pixels arranged in matrix and capable of acquiring an image over a desired range at a time. The capacitance sensor may be the one including a plurality of electrodes arranged in matrix and capable of detecting an image of a fingerprint over a desired range at a time. A specific structure of the biometric authentication apparatus is arbitrary. Further, it is feasible to move the biometric information acquisition apparatus by a mechanical means, rather than moving the finger. A method of creating one authentication image from separated images may be also arbitrary.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A biometric information acquisition apparatus comprising:
a light illuminator that illuminates a subject with light at least over a range corresponding to a pixel arrangement region where a plurality of pixels to receive light from the subject are arranged; and
an imager placed on the same plane as the light illuminator and including the pixel arrangement region.

2. The biometric information acquisition apparatus according to claim 1, wherein
one or more pixel arrays each including the plurality of pixels are formed in the pixel arrangement region.

3. The biometric information acquisition apparatus according to claim 2, wherein
the light illuminator comprises a light guide extending along a pixel arrangement direction in the pixel array.

4. The biometric information acquisition apparatus according to claim 2, wherein
the light illuminator comprises an organic light emitting layer extending along a pixel arrangement direction in the pixel array.

5. The biometric information acquisition apparatus according to claim 1, wherein
the light illuminator comprises a plurality of light emitting devices arranged at substantially regular intervals.

6. The biometric information acquisition apparatus according to claim 2, wherein
the light illuminator uniformizes light within a range corresponding to the pixel array for outputting uniform light.

7. The biometric information acquisition apparatus according to claim 2, wherein
the light guide has a light output surface extending along a pixel arrangement direction in the pixel array.

8. The biometric information acquisition apparatus according to claim 7, wherein
the light guide and the imager are sequentially arranged in a direction intersecting with the pixel arrangement direction in the pixel array.

9. The biometric information acquisition apparatus according to claim 8, further comprising:
a substrate where at least the light guide and the imager are mounted.

10. The biometric information acquisition apparatus according to claim 8, further comprising:
a capacitance sensor including one or more electrode arrays each having a plurality of electrodes arranged along the pixel arrangement direction in the pixel array, wherein the capacitance sensor and the imager are sequentially arranged in a direction intersecting with the pixel arrangement direction in the pixel array.

11. The biometric information acquisition apparatus according to claim 2, wherein
the light illuminator comprises:
a first light source and a second light source to emit light with different wavelengths;
a first light guide to guide light emitted from the first light source and output the light to the subject; and
a second light guide to guide light emitted from the second light source and output the light to the subject, and
the first light guide, the second light guide and the imager are arranged in a direction intersecting with a pixel arrangement direction in the pixel array.

12. The biometric information acquisition apparatus according to claim 11, wherein
the first light source emits near-infrared light, and
the second light source emits visible light.

13. The biometric information acquisition apparatus according to claim 1, further comprising:
a plurality of lenses arranged corresponding to the plurality of pixels.

14. The biometric information acquisition apparatus according to claim 13, further comprising:
a light shielding layer placed between the plurality of lenses and the imager, wherein
the light shielding layer has a plurality of optical openings corresponding to optical axes of the lenses.

15. A biometric authentication apparatus comprising:
a light illuminator to illuminate a subject with light at least over a range corresponding to a pixel arrangement region where a plurality of pixels to receive light from the subject are arranged; and
a semiconductor device placed on the same plane as the light illuminator and including the pixel arrangement region where the plurality of pixels are arranged, the semiconductor device comprising:
an imaging region to capture an image of the subject at least in the range corresponding to the pixel arrangement region;
an authentication region to perform authentication by comparing biometric information acquired by imaging in the imaging region with prestored biometric information; and
a first transfer region to transfer the biometric information acquired by imaging in the imaging region from the imaging region to the authentication region.

16. The biometric authentication apparatus according to claim 15, wherein
the semiconductor device further comprises:
an interface region to supply an authentication result in the authentication region to an external host device; and
a second transfer region to transfer a signal indicating an authentication result in the authentication region to the interface region.

17. The biometric authentication apparatus according to claim 15, wherein
the semiconductor device further comprises:
an encryption region to encrypt an authentication result in the authentication region.

18. The biometric authentication apparatus according to claim 15, wherein
the semiconductor device further comprises:
a control region to control luminance of light illuminated on the subject.
